(19) United States
(12) Patent Application Publication
(10) Pub. No.: US 2023/0363117 A1
(43) Pub. Date: Nov. 9, 2023

(54) System and Method for Sidecar Cooling System

(71) Applicant: Hoffman Enclosures Inc., Anoka, MN (US)

(72) Inventors: Abhishek Gupta, Anoka, MN (US); Stefan Djuranec, Anoka, MN (US); Matthew R. Archibald, Derry, NH (US); Dietmar Mann, Anoka, MN (US)

(21) Appl. No.: 18/312,557

(22) Filed: May 4, 2023

Related U.S. Application Data
(60) Provisional application No. 63/338,311, filed on May 4, 2022.

(51) Int. Cl. H05K 7/20

(52) U.S. Cl. CPC H05K 7/20781; H05K 7/20836; H05K 7/20272

(57) ABSTRACT

Embodiments of the invention provide a high-density liquid cooling system including a cabinet with side panels on opposing sides of the cabinet. A heat exchanger is mounted within the cabinet, and is positioned at an oblique angle relative to the side panels. The heat exchanger is fluidly positioned along a liquid cooling circuit and includes a fluid inlet for receiving a fluid of the liquid cooling circuit. A fan assembly is mounted at a front of the cabinet and includes a plurality of fans configured to generate an air flow across a surface of the heat exchanger. A pumping unit within the cabinet includes a control unit and a first pump for inducing a flow of the fluid of the liquid cooling circuit. The control unit includes a first and second removable controller, and the control unit is electrically connected with the first pump and at least one fan.

### CROSS REFERENCE TO RELATED APPLICATIONS

This application claims priority to U.S. Provisional Patent Application No. 63/338,311 filed May 4, 2022, the entirety of which is incorporated by reference.

### BACKGROUND

Cooling systems can be provided for electrical components in data centers. In some cases, equipment in a data center can be cooled through various means, including through liquid-based cooling systems, air-based cooling systems, or combinations thereof. Electrical equipment within a data center can be housed in racks and can include piping and manifolds for receiving a liquid coolant pumped through a liquid cooling circuit. The liquid coolant can be delivered to components of electrical equipment to provide a heat transfer from those components to the heat of the liquid coolant circuit.

### SUMMARY

Embodiments of the invention can provide improved cooling systems. Some embodiments of the invention provide a system and method for a high-density liquid cooling system including a cabinet including side panels on opposing sides of the cabinet. A heat exchanger can be within the cabinet, the heat exchanger being positioned at an oblique angle relative to the side panels. The heat exchanger can be fluidly positioned along a liquid cooling circuit and can include a fluid inlet for receiving a fluid of the liquid cooling circuit. A fan assembly can be mounted at a front of the cabinet, the fan assembly including a plurality of fans, the plurality of fans being configured to generate an air flow across a surface of the heat exchanger. A pumping unit can be provided within the cabinet, the pumping unit including a control unit and a first pump for inducing a flow of the fluid of the liquid cooling circuit. The control unit can include a first removable controller and a second removable controller, and the control unit being in electronic communication with the first pump and at least one fan of the plurality of fans.

In some embodiments, an in-row liquid cooling system includes a liquid-to-air heat exchanger, a pumping unit, a fan, a first sensor, a second sensor, and a controller. The liquid-to-air heat exchanger can be positioned along a liquid cooling circuit, the liquid-to-air heat exchanger including a liquid inlet and a liquid outlet. T pumping unit can include a liquid pump, the liquid pump being configured to generate a fluid flow in a liquid coolant of the liquid cooling circuit. The fan can be configured to generate an air flow across a surface of the liquid-to-air heat exchanger. The first sensor can be configured to measure a first value of a first parameter of the liquid coolant. The second sensor can be configured to measure a second value of a second parameter of the liquid coolant. The controller can be in electrical communication with each of the liquid pump, the fan, the first sensor and the second sensor. The controller including a processor configured to: receive, from the first sensor, the first value; receive, from the second sensor, the second value; based on a comparison of the first value with a target value for the first parameter, output to the liquid pump, a signal to change a speed of the liquid pump; and based on a comparison of the second value with a target value for the second parameter, output to the fan a signal to change a speed of the fan.

In some embodiments, a method of manufacturing and operating a cooling system can be provided. The method can include providing an enclosure having side panels at opposing lateral sides of the enclosure. An air-to-liquid heat exchanger can be mounted within the enclosure, the air-to-liquid heat exchanger being mounted at an oblique angle relative to the side panels. A replaceable pump unit can be mounted within the enclosure, the replaceable pump unit including at least two pump cassettes and a control unit including two removable control modules. A fan assembly can be mounted at a front of the enclosure, the fan assembly including a plurality of removable fans. The air-to-liquid heat exchanger can be fluidly connected with at least one pump cassette of the at least two pump cassettes. A first replaceable control module of the two removable control modules can be electrically connected to at least one of the fans of the plurality of fans, and at least one pump. In response to a signal from the first replaceable control module, an air flow across the air-to-liquid heat exchanger can be regulated, using at the at least one of the fans. In response to a signal from the first replaceable control module, a flow of fluid through the air-to-liquid heat exchanger can be regulate, using the at least one pump.

In some implementations, devices or systems disclosed herein can be utilized, manufactured, installed, etc. using methods embodying aspects of the invention. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a schematic of a coolant distribution system, according to an embodiment of the invention;

FIG. 2 is an isometric view of a liquid-to-air cooling unit, according to an embodiment of the invention;

FIG. 3 is a rear, left isometric view of the liquid-to-air cooling unit of FIG. 2;

FIG. 4 is a front elevation view of the liquid-to-air cooling unit of FIG. 2;

FIG. 5 is a front, right view of the liquid-to-air cooling unit of FIG. 2, with side panels of the unit removed;

FIG. 6 is a rear, left isometric view of the liquid-to-air cooling unit of FIG. 2 with the side panels removed;

FIG. 7 is a section view of the liquid-to-air cooling unit, showing the liquid-to-air heat exchanger within the unit at an oblique angle relative to the side walls of the unit;

FIG. 8 is a top plan section view of the liquid-to-air cooling unit of FIG. 2, showing the liquid-to-air heat exchanger within the unit at an oblique angle relative to the side walls of the unit;

FIG. 9 is a section views of the liquid-to-air cooling unit of FIG. 2, showing a mounting bracket securing the heat exchanger to the unit;

FIG. 10 is a partial view of components of the liquid-to-air cooling unit of FIG. 2, illustrating plumbing elements in a top portion of the unit;

FIG. 11 is a partial view of components of the liquid-to-air cooling unit of FIG. 2, illustrating plumbing elements in a bottom portion of the unit;

FIG. 12 is a partial front, right view of the liquid-to-air cooling unit of FIG. 2, showing a pumping unit installed in the bottom slot of the unit;

FIG. 13 is an isometric view of a manifold of the liquid-to-air cooling unit of FIG. 2;

FIGS. 14 and 15 are isometric views of a filter assembly of the liquid-to-air cooling unit of FIG. 2;

FIG. 16 is a rear isometric view of expansion tanks of a liquid-to-air cooling unit, according to some embodiments;

FIGS. 17 and 18 are isometric views of a heat exchanger used in the liquid-to-air cooling unit of FIG. 2;

FIGS. 19 and 20 are isometric views of fan units used in the liquid-to-air cooling unit of FIG. 2;

FIG. 21 is an isometric view of an control unit for use with a pumping unit of the liquid-to-air cooling unit of FIG. 2 according to embodiments of the invention;

FIG. 22 is an isometric view of a power supply unit of the liquid-to-air cooling unit of FIG. 2, according to some embodiments of the invention;

FIG. 23 is a front, right isometric view of a power supply unit for use with liquid-to-air cooling units;

FIG. 24 is a front, right isometric view of an environmental monitoring platform, according to embodiments of the invention;

FIG. 25 is a system schematic of high-density liquid cool units, according to some embodiments of the invention;

FIG. 26 is a system schematics of high-density liquid cooling units, according to some embodiments of the invention;

FIGS. 27 and 28 are schematics for feedback control systems for high-density liquid cooling systems;

FIGS. 29A-29C are system schematics showing a controller, and an interface board for controlling elements of a high-density liquid cooling system;

FIGS. 30A-1 through 30B-2 are a list of sensors that can be used with a liquid-to-air cooling unit, according to some embodiments;

FIG. 31 is a schematic of a control system for a liquid-to-air cooling unit, according to some embodiments;

FIG. 32 is a schematic of a controller, which can be used as a controller of a liquid-to-air cooling unit, according to some embodiments; and

FIG. 33 is a flowchart illustrated an example control process of a liquid-to-air cooling unit, according to some embodiments.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

In some implementations, devices or systems disclosed herein can be utilized, manufactured, installed, etc. using methods embodying aspects of the invention. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

In some embodiments, aspects of the invention, including computerized implementations of methods according to the invention, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, embodiments of the invention can be implemented as a set of instructions, tangibly embodied on a non-transitory computer-readable media, such that a processor device can implement the instructions based upon reading the instructions from the computer-readable media. Some embodiments of the invention can include (or utilize) a control device such as an automation device, a special purpose or general-purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some embodiments, a control device can include a centralized hub controller that receives, processes and (re)transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally, it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the invention, or of systems executing those methods, may be represented schematically in the FIGS., or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the invention. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also as used herein, unless otherwise limited or defined, the terms “about,” “substantially,” and “approximately” refer to a range of values ±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise defined or limited, the term “lateral” refers to a direction that does not extend in parallel with a reference direction. A feature that extends in a lateral direction relative to a reference direction thus extends in a direction, at least a component of which is not parallel to the reference direction. In some cases, a lateral direction can be a radial or other perpendicular direction relative to a reference direction.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Cooling systems can be provided for data centers to cool electrical components within a data center. During operation, electrical components, typically housed in racks having a standard rack footprint (e.g., a standard height, width, and depth), generate heat. As that heat may degrade electrical components, damage the systems, or degrade performance of the components, cooling systems can be provided for data centers for transferring heats away from racks of the data center with electrical components that need to be cooled.

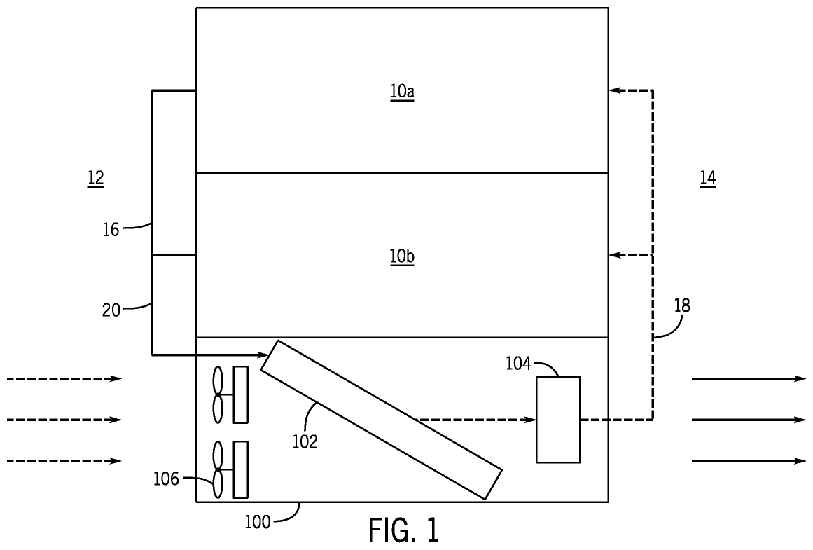

Cabinets or racks containing electrical equipment are typically arranged in rows within a data center, defining aisles between consecutive rows. Racks can be pre-assembled and “rolled in” to a space in the row adjacent to other racks, the space being pre-defined to have the footprint of a standard rack. This arrangement allows a modular construction of or addition to components in a data center. In some configurations, aisles on opposite sides of a row of cabinets can be alternately designated as a cold aisle, or a hot aisle, and heat generated by the electrical components of a cabinet can be expelled to the hot air aisle, as shown in FIG. 1.

FIG. 1 illustrates a schematic for a cooling system 1, according to some embodiments of the invention. As described above, electrical equipment (e.g., servers, storage devices, networking devices, etc.) within a data center can generate heat in operation and can require cooling systems to dissipate or transfer heat away from the electrical components. FIG. 1 illustrates cabinets 10a, 10b housing electrical equipment that can be a load of the cooling system 1. As shown, cabinets 10a, 10b are arranged in a row, with a front of each of the cabinets facing a cold aisle 12, and a rear of each of the cabinets 10a, 10b facing a hot aisle 14. As shown, both cabinets 10a, 10b can be in the flow path of a liquid coolant circuit 16 (e.g., a liquid cooling loop), and a coolant of the liquid coolant circuit 16 can flow through the cabinets 10a, 10b to transfer heat from electrical components in the cabinets 10a, 10b. For example, the liquid coolant circuit 16 can include a cold side 18 having a cooled fluid, and a hot side having 20 having a heated fluid. As shown, coolant from the cold side 18 can flow into each of the cabinets 10a, 10b, and can be heated by a heat transferred to the fluid from electrical components within the cabinets 10a, 10b. The heated fluid can then flow out of the electrical cabinets 10a, 10b to the hot side 20 of the liquid coolant circuit 16 to transfer the heat away from the respective electrical cabinets 10a, 10b. In some examples, a liquid coolant within a liquid coolant circuit (e.g., liquid coolant circuit 16) can be water. In some examples, the liquid coolant can be a dielectric fluid. In some examples, the liquid coolant can be a propylene glycol, or a combination of water and an anti-corrosion agent.

While the above description references cabinets of electrical equipment within a data center, it should be noted that the disclosure is not limited to cooling electrical cabinets within a data center and can be equally applicable to any application or use case requiring liquid cooling. For example, cabinets along a first liquid coolant circuit (e.g., one or more of cabinets 10a, 10b along liquid coolant circuit 16) can house liquid to liquid heat exchangers which can transfer heat from a coolant of a second liquid coolant circuit to the liquid of the first liquid coolant circuit. In some cases, liquid cooling circuits and systems can be provided for power supply systems, and can be used to cool batteries, transformers, power converters, electric motors, and the like. In some cases, liquid coolant circuits consistent with this disclosure can be used to cool thermal loads outside of data centers.

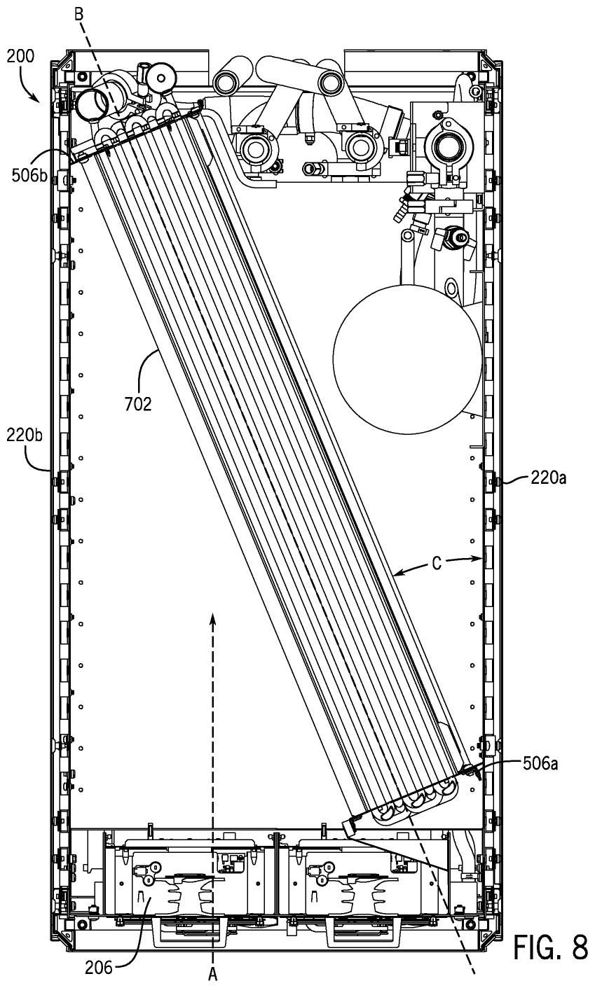

Cooling systems can include liquid-to-air cooling units to transfer heat from a liquid of a liquid cooling circuit (e.g., liquid coolant circuit 16) to an air of a data center (e.g., air of the hot aisle 14). As will be discussed further, the in-row cooling unit can be housed in a rack having a standard rack footprint for modular assembly, ease of installation and integration within a data center. In other embodiments, the footprint of an in-row cooling unit may be smaller than a standard rack footprint. As further illustrated in FIG. 1, the cooling system 1 can include an in-row liquid-to-air cooling unit 100 (LACU) for transferring heat from the fluid of the liquid coolant circuit 16 to air of the hot aisle 14. The LACU 100 can be housed in a rack, within an aisle of electrical equipment. For example, as shown, the LACU 100 can be in a row with electrical cabinets 10a, 10b along the liquid coolant circuit 16, with a front of the LACU 100 facing the cold aisle 12 and a rear of the LACU facing the hot aisle 14. The LACU 100 can include a liquid-to-air heat exchanger 102 (HX) for transferring a heat from fluid in the liquid coolant circuit 16 to air of the data center (e.g., air of the hot aisle 14). The liquid from the hot side 20 of the liquid coolant circuit 16 can enter the HX 102, and the liquid can exit the HX 102 to the cold side 18 of the liquid coolant circuit 16. A surface area of a liquid to air heat exchanger can correspond to a rate of heat transfer from a liquid to air, and a greater surface area of the heat exchanger can correspond to a greater rate of heat transfer. Thus, a heat exchanger of a liquid-to-air cooling unit can be sized and positioned to provide maximal surface area for heat transfer. For example, as shown in FIG. 1, the HX 102 can be positioned at an oblique angle within the LACU 100 relative to sides of the LACU 100 (e.g., as further described with respect to FIG. 8).

In some examples, liquid-to-air cooling units can include air flow components (e.g., fans) to induce a flow of air across a liquid-to-air heat exchanger to increase a heat transfer from liquid of a liquid coolant circuit to an air of the data center. For example, as shown, the LACU 100 can include one or more fans 106 to induce a flow of air across the HX 102. The one or more fans 106 can be positioned at a front of the LACU 100 and can suck in cool air from the cold aisle 12 and blow the air across the HX 102 in a direction toward the hot aisle 14. In some examples, fans of a liquid-to-air cooling unit can be position in a back of the cabinet. In some examples, fans of a liquid-to-air cooling unit can suck air from a rear of the unit across a heat exchanger and blow the air out of a front of the unit (e.g., air can flow in an opposite direction from the air flow direction shown). As discussed below, fans of an air-to-liquid cooling unit can be arranged in rows and columns along a front of the unit.

According to some embodiments, a cooling system for electrical equipment can include one or more pumping units to induce a flow of fluid through a liquid coolant circuit. In some embodiments, the cooling system may not include a pumping unit, but may instead rely on water pressure provided by the facility in which the cooling system is installed. In some examples, a pumping unit can be housed in an in-row liquid-to-air cooling unit (e.g., the liquid-to-air cooling unit can be a coolant distribution unit). As further shown in FIG. 1, the LACU 100 can include a pumping unit 104 to pump fluid through the liquid cooling circuit 16. It can be advantageous to pump cool fluid through pumps of a pumping unit, as warm fluid can cause an expansion in components of the pumps, which can decrease a lifetime of the pumps. In some cases, as described below, the pumping unit 104 can include a plurality of pumps. The pumping unit 104 can be positioned downstream of the HX 102 and can be along the cold side 18 of the liquid coolant circuit 16. In other examples, a pumping unit of a liquid-to-air cooling unit can be upstream of a liquid-to-air heat exchanger (e.g., pumps of the liquid-to-air cooling unit can be along a hot side of a liquid cooling circuit). A pumping unit of a liquid-to-air cooling unit can be provided to fit in a standard size slot within a cabinet (e.g., a height of 2 U, or 4U, or 8U or occupying four vertical bays of the cabinet). In some embodiments, a coolant distribution unit (CDU) can be provided in the in-row liquid-to-air cooling unit, rather than in the cabinet housing electrical equipment.

In the illustrated embodiment, the cold side 20 of the liquid cooling circuit 16 is shown at a front side of each of the cabinets 10a, 10b and the LACU 100, and the hot side 18 is shown at a rear side of the cabinets 10a, 10b and the LACU 100. However, in some embodiments, it can be advantageous to position liquid entries and exits (e.g., inlet ports and outlet ports) on a same side of a cabinet. For example, liquid manifolds for fluid entry and exit for cabinets can be mounted at a rear of the respective cabinets. In some examples, hosing of a liquid cooling circuit can enter cabinets (e.g., cabinets of electrical equipment or a cabinet of a liquid-to-air cooling unit) from a rear of the cabinet, through an entry in a side panel of the cabinet, from a top entry, or from a bottom entry of the cabinet. Further, in some embodiments, a liquid-to-air cooling unit can be provided to cool more than two electrical cabinets, or only one electrical cabinet.

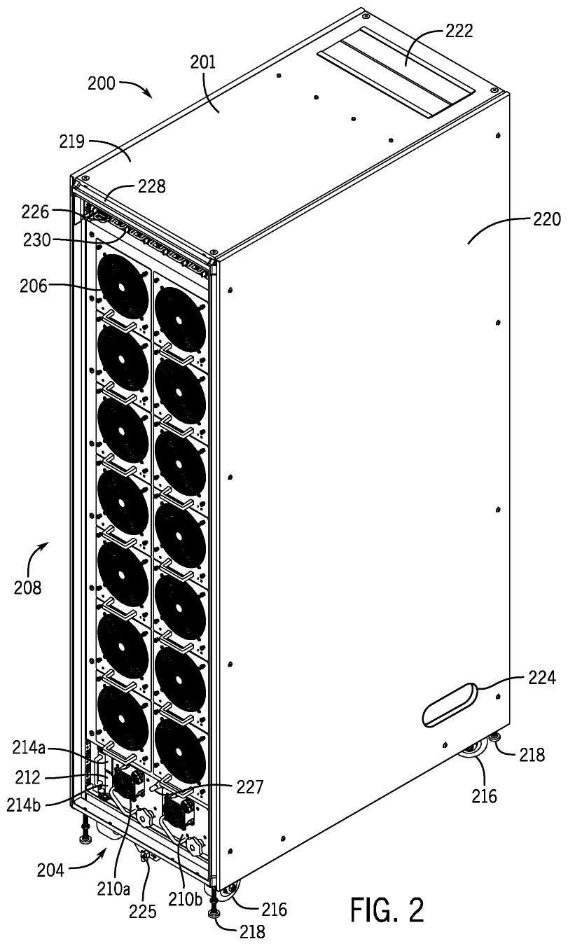

FIG. 2 illustrates an exemplary liquid-to-air cooling unit (LACU) 200, alternatively referred to as a “sidecar” or a coolant distribution unit (CDU). The LACU 200 can be similar to, or substantially identical to LACU 100 described above with respect to FIG. 1 and can include similar numbering for similar components. For example, a plurality of fans 206 can be provided in a fan assembly 208 in a front of the cabinet, as illustrated, which can induce an airflow through the system, increasing the cooling efficiency thereof. In the illustrated embodiment, the fan assembly 208 includes fourteen fans 206 arranged in two columns and seven rows. In some embodiments, a LACU can include more than 14 fans or fewer than 14 fans. In some cases, fans can be arranged in panels including four fans in a single panel, for example. As discussed below, the fans 206 can be hot-swappable (e.g., individual fans 206 of the fan assembly can be removed, replaced, or serviced without causing a downtime of the LACU 200).

It can be advantageous to position pumping units in a bottom of a rack of a liquid-to-air cooling unit (e.g., LACU 200), to prevent any leakage of fluid (e.g., liquid leaks during replacement of components of the pumping units) from producing damage to electronics of the liquid-to-air cooling unit. For example, as further shown in FIG. 2, the LACU 200 can include a replaceable pump unit (RPU) 204. The RPU 204 can be housed beneath the fan assembly 208 and can have a height of four rack units (e.g., the RPU 204 can have a height of 4 U, occupying a space equal to four standard shelves of electrical equipment within a cabinet of a data center). The RPU 204 can include two pump cassettes 210a, 210b, and a control unit 212 including two hot-swappable control modules 214a, 214b. In some embodiments, the pump cassettes 210a, 210b can be hot-swappable, and can include blind connectors (not shown) in a back portion of the pump cassette 210a, 210b for electrical and fluid connections. In some embodiments, an RPU can include only one pump cassette, or more than two pump cassettes. In some examples, an RPU can occupy a greater volume within a LACU (e.g., the RPU can have a height of 8 U). In some embodiments, the hot-swappable control modules 214a, 214b are substantially similar, and when one hot-swappable control module 214a, 214b is removed for servicing or replacement, the other hot-swappable control module 214a, 214b can implement control processes for the LACU 200, as further described below. In some examples, an RPU does not include a control module (e.g., a main controller for a liquid-to-air cooling unit can be housed at a different location within the cooling unit, or external to the cooling unit), or includes only one control module, or more than two control module.

A liquid-to-air cooling unit can include a fill/drain port for filling the unit and components of the unit with liquid coolant (e.g., charging the unit). In some cases, it can be advantageous to provide a fill/drain port of a liquid-to-air cooling unit at a front of the unit, to be accessible to an operator of the unit from a cold aisle. As shown, the LACU 200 can include liquid fill/drain port 225 at a bottom of the LACU 200. Positioning the fill/drain port at a bottom of the LACU 200 can be advantageous, as it can reduce a pressure to drain the system. In some cases, the fill/drain port 225 can comprise a quick disconnect fitting, to provide for an ease of connecting fill or drain lines to the LACU 200. In other embodiments, a liquid-to-air cooling unit can include more than one port, including, for example, a dedicated fill port and a dedicated drain port. In some examples, ports can be provided at the front of a LACU corresponding to individual components of the LACU. For example, as shown, the RPU 204 can include a liquid fill/drain port 227 for filling or draining a fluid from the RPU 204. In some cases, liquid fill/drain ports can be provided at other locations of a LACU, including in a back, along a side, etc.

As shown, the LACU 200 can be housed within a cabinet 201. The cabinet 201 can have a standard rack footprint, and may have a width of 600 mm, as can allow the cabinet to be “rolled in” to a cabinet space within a row of cabinets in a data center. In some embodiments, a cabinet, which can also be referred to as a “rack” or an “enclosure” can have different rack footprints. For example, in some cases a rack can have a width of 1200 mm to occupy a space within a row in a data center that is sized to receive two adjacent racks of equipment. In some cases, a cabinet of a liquid-to-air cooling unit can occupy a footprint with a width of less than 600 mm, or greater than 600 mm. In some cases, a width or height of a cabinet of a liquid-to-air cooling unit can be configured to meet a standard, including, for example, an industry standard, or a regulatory standard.

A cabinet of a liquid-to-air cooling unit can include features to facilitate ease of installation and integration within a data center. For example, as illustrated, the LACU 200 can include a plurality of wheels 216 to allow the LACU 200 to be rolled to a desired location within a data center. In some embodiments, a liquid-to-air cooling unit can include casters. The LACU 200 can also include a plurality of adjustable feet 218. Before the LACU 200 is in an installation position, the plurality of adjustable feet 218 can be positioned at a first height, and at the first height, the adjustable feet do not engage or contact a floor of the data center. When the LACU is installed in a desired location, the adjustable feet 218 can be moved to a second height (e.g., by rotating an adjustable screw), at which the adjustable feet 218 engage the floor and prevent displacement of the LACU 200 relative to the floor. In some embodiments, a liquid-to-air cooling unit may not include wheels and adjustable feet or can include alternative or additional known mechanisms for facilitating an ease of installation and securing the unit in place when installed.

A cabinet of a liquid-to-air cooling unit can include panels, which can function to enclose components of the unit, partially define a flow path of air through the cabinet, can further shield internal components from view. As further shown in FIG. 2, for example, the cabinet 201 can include a top panel 219 at a top of the cabinet 201, and one or more side panels 220 at lateral sides of the cabinet 201 (e.g., along vertical sides of the LACU 200 not facing either a hot aisle or a cold aisle). In some embodiments, cables for electrical power and hosing for fluid connections can enter cooling units through an open back portion of the cooling unit (not shown). In some cases, however, it may be advantageous to provide cable and hose entries for cabinets of cooling units at other locations. For example, feeding cables and hoses through a back of the cabinet can increase a depth required for a row housing a cooling unit. In some cases, data centers can be arranged with top feed configurations, with connections (e.g., cables, tubing, hosing etc.) being provided from a ceiling. In other configurations, cabinets in a data center are installed on a raised floor, and connections can be provided from a bottom of the cabinet (i.e., in a “bottom feed” configuration). In this regard, panels of a cabinet of a cooling unit can include openings, which can be referred to as apertures or cutouts, to provide an entry for cables and hosing into the cabinet. For example, as shown in FIG. 2, the top panel 219 can include a top-feed cutout 222, for receiving cable and hosing from a top of the cabinet. Similarly, a bottom-feed cutout (not shown) can be provided at a bottom of the cabinet to receiving cabling and hosing through a bottom of the cabinet. In some cases, it can be advantageous to route hosing directly from adjacent cabinets. For example, providing liquid connections directly from an adjacent cabinet can reduce a pressure needed to pump coolant through a liquid coolant circuit. This configuration can reduce a total length of tubing required for a system, which in turn reduces the power required to pump coolant through the system. Additionally, when routing hosing directly through the cutout in the side panel, hosing need not extend out a back portion of either the electrical cabinet or the cabinet housing the cooling system, which may reduce a clearance needed or a total depth of the system. As shown, the side panel 220 can have a side cutout 224 for receiving hosing and/or hosing directly from adjacent cabinets. In some examples, hosing and cabling can enter a cabinet at other locations than illustrated, including, for example, through a front of a cabinet. In some cases, cutouts for receiving hosing into a cooling unit can have an open area that is at least large enough to accommodate 4 hoses having a diameter of 1.5 inches.

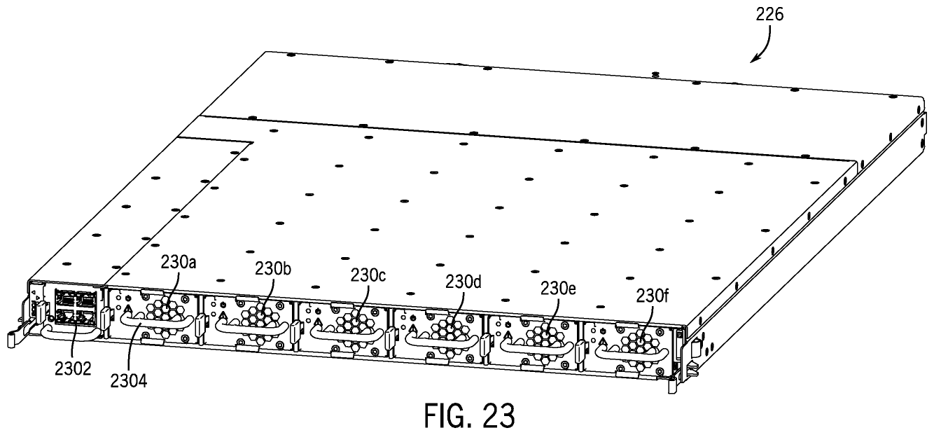

Cooling units for use in data centers, including liquid-to-air cooling units described herein can include power supply modules for controlling aspects of an electrical power provided to electrical components of the cooling unit. For example, as further shown in FIG. 2, the LACU 200 can include a power supply unit 226. As shown, the power supply unit 226 can be provided at or near a top of the LACU 200 (e.g., above liquid flow components in the LACU 200). This arrangement can be advantageous, as it can prevent leakage of liquid onto power control elements of the power supply unit 226. In the illustrated embodiment, the power supply unit 226 has a height of 1 U, and an empty slot 228 is provided above the power supply unit 226, the empty slot having a height of 1 U. In some embodiments, a power supply unit of a cooling unit can have a height of 2 U. In some examples, a cooling unit (e.g., the LACU 200) can include two power supply units. Power supply units for liquid-to-air cooling unit can include one or more removable power modules 230, as further described with respect to power supply unit 2300 shown in FIG. 23. In the illustrated embodiments, the power supply unit 226 includes 6 power supply modules, but in other embodiments, a power supply unit of a cooling unit can include only one power supply module, or at least two power supply modules, at least three power supply modules, at least four power supply modules, or at least five power supply modules. In some examples, a power supply unit can include more than six power supply modules. In some embodiments, a power supply unit can receive three phases of power from a power inlet, and individual phases of the three phases can be provided to a respective power supply module. Thus, it can be advantageous to provide power supply modules in multiples of three to correspond to three phases of a power inlet and allow balancing of phases across power supply modules.

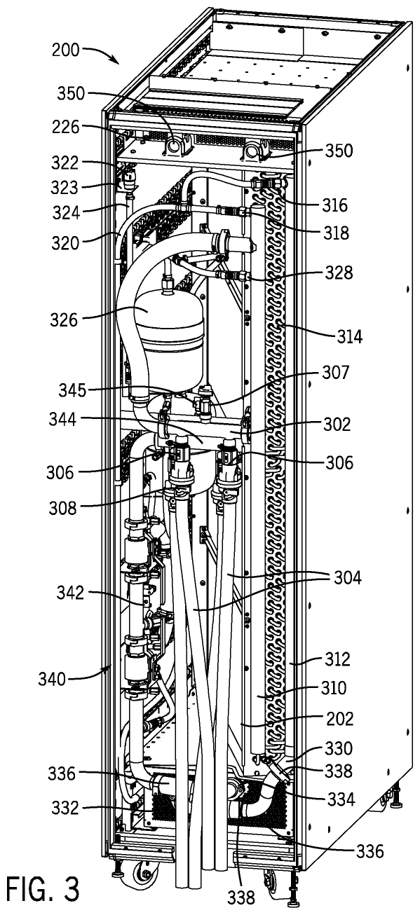

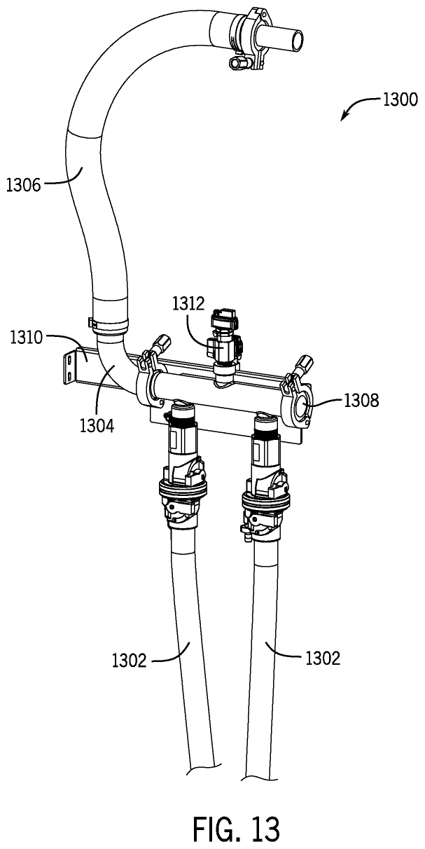

A liquid-to-air cooling unit (e.g., LACUs 100 shown in FIGS. 1 and 200 shown in FIG. 2) can include plumbing elements (e.g., piping, hoses, valves, pumps, pressure regulation devices, etc.) for directing a flow of fluid through the unit. Plumbing elements can be housed primarily in a rear of a cabinet of a liquid-to-air cooling unit, as can improve an ease of servicing and reduce a pressure drop across plumbing elements that may otherwise be incurred if plumbing elements were dispersed through the unit. For example, FIG. 3 is a rear isometric view of the LACU 200, showing a plurality of plumbing and flow control elements of the LACU 200. As described above, a liquid-to-air cooling unit can receive heated fluid from a hot side of a fluid coolant circuit (e.g., the hot side 20 of liquid coolant circuit 16, as shown in FIG. 1). In this regard, FIG. 3 illustrates an inlet manifold 302 (e.g., a return manifold) for receiving heated fluid along a hot side of a liquid coolant circuit. In the illustrated embodiment, the inlet manifold 302 receives fluid from two hoses 304, which can each return fluid from respective cabinets of electrical equipment (e.g., cabinets 10a and 10b shown in FIG. 1). As described further with respect to manifold 1300 shown in FIG. 13, the hoses 304 can be connected to the manifold 302 at connection interfaces 306. The connection interfaces 306 can include shutoff valves 308 to block a flow of fluid from the corresponding hose 304 into the LACU 200. If one of the shutoff valves 308 is closed, the LACU 200 can receive heated coolant from only one cabinet, for example. Further, in the illustrated embodiment, the connection interfaces 306 are quick disconnect fittings, as can allow for toolless connection of hoses 304 to the inlet manifold 302 and can minimize a leakage of fluid when one of the hoses 304 is installed or disconnected. In some embodiments, other connection interfaces can be used. For example, hoses of a hot side of a liquid cooling circuit can be connected to an inlet manifold using tri-clamp flanges. In some embodiments, an inlet manifold can be configured to receive heated fluid from more than two cabinets, and can include three connection interfaces, or four connection interfaces, or five connection interface, or six connection interfaces, or more than six connection interfaces, with each connection interface corresponding to hosing providing heated fluid to a liquid-to-air cooling unit from a corresponding cabinet of electrical cabinet.

In the illustrated embodiment, the inlet manifold 302 is positioned and configured to receive hosing 304 from a bottom of the cabinet (e.g., in a bottom-feed configuration). In some embodiments (e.g., as further described with respect to manifold 1300), the manifold 302 can be positioned and configured to receive hosing (e.g., hosing 304) in a top-feed configuration, with the connection interfaces 306 extending upwardly from the inlet manifold 302. In other embodiments, a manifold can be differently positioned in a LACU. For example, while in the illustrated embodiment, the manifold 302 receives hosing 304 in a vertical direction, in other embodiments, a manifold can extend vertically within a cabinet of a LACU and can receive hosing from a direction that is orthogonal or substantially orthogonal to a vertical direction (e.g., from a horizontal direction). In some cases, a liquid-to-air cooling unit may not include an inlet manifold and hosing from electrical cabinets can connect directly to plumbing elements of the cooling unit.

It can be advantageous to measure parameters of a fluid flowing into a cooling unit (e.g., LACU 200). For example, an inlet temperature of a fluid in a cooling unit can be measured and compared to an outlet temperature of fluid of a cooling unit to determine a total cooling rate for the unit. As shown, the inlet manifold can include a sensor module 307. The sensor module 307 can include one of more sensors for measuring a parameter of a fluid at the inlet. For example, the sensor module can include a temperature sensor, a pressure sensor, a flow rate sensor, etc. Values from sensors of the sensor module 307 can be compared to values from other sensors along the liquid coolant circuit, as can facilitate a calculation of efficiency and cooling power provided by one or more components of LACU 200. As an example, an outlet manifold 344 can include a sensor module 345 which can be substantially identical to the sensor module 307, and a temperature value from a sensor of the sensor module 345 can be compared to a temperature value from a temperature sensor of the sensor module 307 to obtain a differential temperature between the inlet and outlet of the LACU 200. In some embodiments, a differential pressure or flow rate can be calculated additionally or alternatively to the differential temperature measurement described.

Liquid coolant of a liquid coolant circuit can flow directly from an inlet (e.g., an inlet manifold) into a liquid-to-air heat exchanger. It can be advantageous to cool a liquid before providing the liquid to other plumbing elements or flow control components (e.g., pumps), as heated liquid can produce more wear on components than a cooled liquid. In this regard, FIG. 3 illustrates a liquid-to-air heat exchanger 202 (LAHX) positioned within the LACU 200. The LAHX 202 includes an inlet pipe 310 for receiving a heated fluid, and an outlet pipe 312 for outputting a cooled fluid from the LAHX 202. Additionally, the LAHX 202 can include a plurality of internal loops 314 to increase a length of a flow path of coolant through the LAHX 202 and maximize a surface area available for heat transfer between the fluid of the liquid coolant circuit and air.

Inlet and outlet pipes of an air-to-liquid heat exchanger can include ports for injecting liquid into the liquid-to-air heat exchanger and, removing air or liquid from the liquid cooling circuit, or regulating pressure along the liquid coolant circuit. For example, components of a liquid cooling system can be “charged” (e.g., filled) with a coolant before installation or operation of the system. Additionally, system components can be drained of fluid in the system, including, for example, when the component is removed for servicing, or when a coolant of a system is replaced. Thus, a liquid-to-air cooling unit can include fluid fill and drain ports to charge all components of the unit, and individual components of the unit can also include liquid fill and drain ports to charge the individual components. For example, as shown, the LAHX 202 can include a liquid port 316 along the outlet pipe 312 and a liquid port 318 along the inlet pipe 310. Either or both of the liquid ports 316, 318 can comprise quick disconnect fittings for selectively connecting fill lines, drain lines, or air bleed lines to the respective liquid ports 316, 318. As shown, the ports are connected to a liquid fill/drain line 320, which can be fluidly connected to the fill/drain port 225 described with respect to FIG. 2. However, in some cases, there is no piping or hosing connected to the ports 316, 318 in normal operation of the LACU 200.

In some cases, air within a liquid coolant circuit can cause damage to components along the liquid cooling circuit, including, for example, to pumps of a liquid cooling circuit, or to electronic components to be cooled. In some cases, air within a liquid cooling circuit can also reduce a total cooling efficiency of the system, so that greater power is required to cool electronic components. Systems can therefore be provided for a liquid-to-air cooling unit to remove air (e.g., bleed air) from piping of a liquid cooling circuit. As air is less dense than water, air bubbles will tend to rise to a highest point along a liquid flow path of a liquid cooling circuit, and therefore, air bleed valves can be provided at points of the liquid flow path of a liquid cooling circuit that are elevated (e.g., vertically higher) relative to other portions of the piping or plumbing elements. As shown in FIG. 3, the liquid ports 316, 318 can be located at or near a top of the respective pipes 310, 312. Flow of fluid from one or more of the ports 316, 318 can be redirected to an air bleed valve 322. In normal operation of the LACU 200, the air bleed valve 322 can be fluidly isolated from the liquid cooling circuit. However, when an operator is performing an air bleed operation (e.g., when initially charging all or a portion of the LACU 200 with a fluid), the air bleed valve 322 can be fluidly connected to either or both of the ports 316, 318 to bleed air therefrom. In some embodiments, as shown, the air bleed valve 322 can include a connection hose 324 which can be connected to either or both of liquid ports 316, 318 to bleed air from the liquid cooling circuit at either respective location. The air bleed valve 322 can be secured to the cabinet with a mounting bracket 323.

In some cases, it can be useful to include components within a liquid-to-air cooling unit to regulate or maintain a set pressure within the unit, or to prevent a pressure from exceeding a certain value. For example, if a heat of a fluid in a liquid cooling circuit increases, the fluid within the circuit can expand, which can increase a pressure along all or a portion of the liquid cooling circuit. As illustrated, the LACU 200 can include an expansion tank 326. The expansion tank 326 can be in fluid communication with the liquid cooling circuit and can receive fluid from the liquid cooling circuit when a pressure in the liquid cooling circuit exceeds a pressure charge of the expansion tank 326. In the illustrated embodiment, the expansion tank is fluidly positioned along a hot side of the liquid cooling circuit and is connected to the inlet pipe 310 of the LAHX 202 at a liquid port 328. The liquid port 328 can be positioned along the inlet pipe 310 to provide pressure regulation on the hot side of the liquid cooling circuit (e.g., where liquid of the liquid cooling circuit is more prone to expansion due to an increased heat relative to other portions of the cooling unit 200). In some embodiments, an expansion tank of a liquid-to-air cooling system can be positioned at other points along a liquid cooling circuit. For example, an expansion tank can be installed downstream of a liquid-to-air heat exchanger, or downstream of a replaceable pump unit. In some embodiments, a liquid-to-air cooling unit may not include an expansion tank. In some embodiments, a liquid-to-air cooling unit can include more than one expansion tank or cannot include an expansion tank.

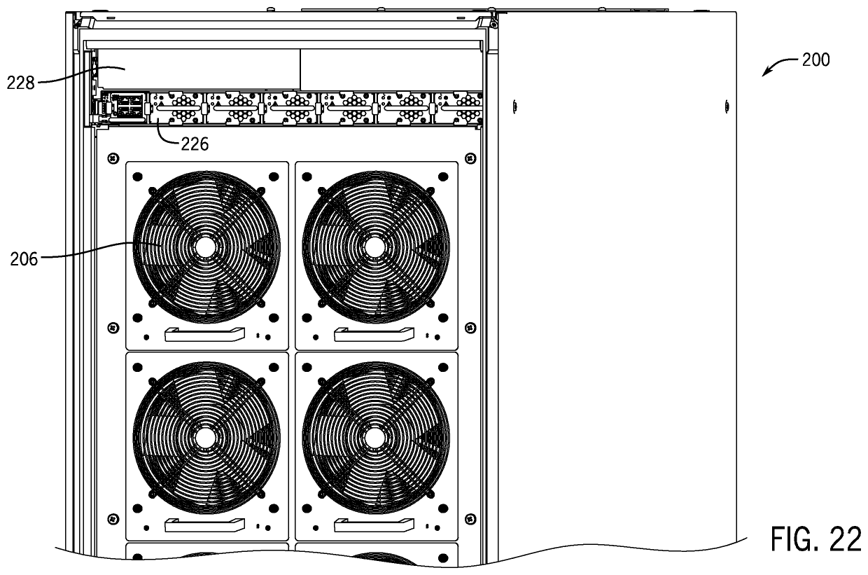

As further shown in FIG. 3, the outlet pipe 312 of the LAHX 202 can be fluidly connected to the RPU 204. For example, an angled elbow connector 330 can be positioned at an outlet end of the outlet pipe and can direct fluid flow generally towards an inlet port 332 of the RPU 204. The angled elbow connector 330 can ensure a smooth (e.g., as opposed to turbulent) flow of fluid into the RPU. Fluid can be pumped through the RPU 204, as further described below, and may exit the RPU 204 at an output port 334. Flexible hosing 336 can be used to fluidly connect the RPU 204 to the liquid cooling circuit, and the flexible hosing 336 can be connected to the ports 332, 334, and other plumbing components (e.g., the outlet pipe 312 or the elbow connect 330) through clamping systems 338 (e.g., tri-clamp flange systems). In other embodiments, cooling units may not include an RPU or pumping units and may rely on a pressure provided from a facility (e.g., as illustrated in schematic of FIG. 21).

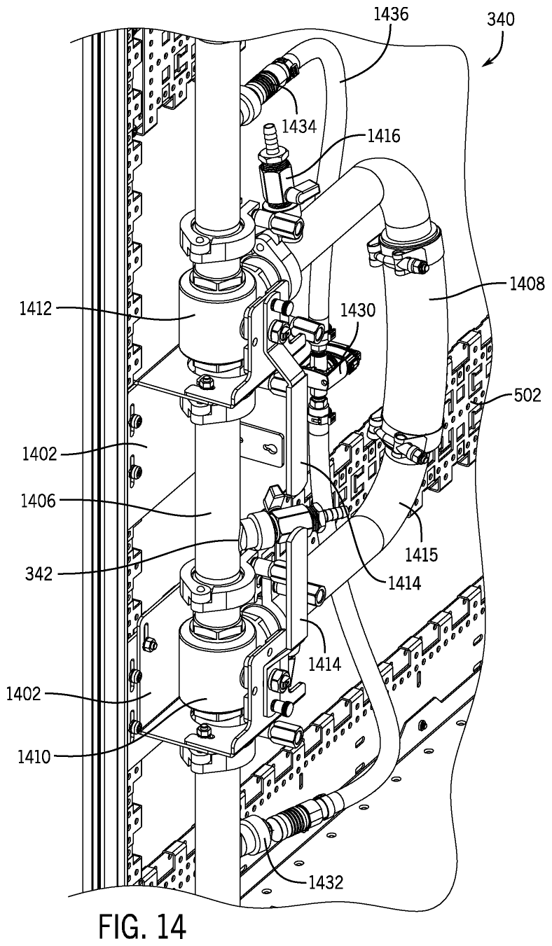

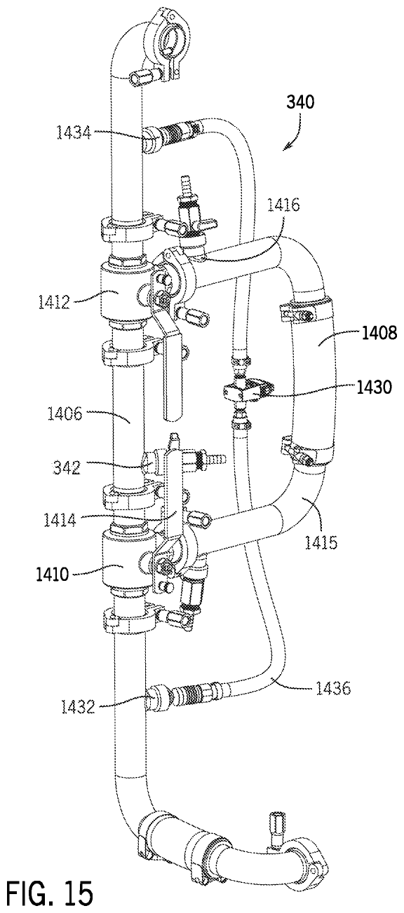

In some cases, it can be advantageous to provide filtration systems for fluid of a liquid cooling circuit (e.g., filers of a liquid-to-air cooling unit). Impurities and particulate matter in a fluid of a liquid cooling circuit can damage plumbing elements along a liquid cooling circuit and electronics cooled by the cooling system, as well as reduce a cooling efficiency. As illustrated in FIG. 3 and described further with respect to FIGS. 14 and 15, a filtration assembly 340 can be provided within the LACU 200. In some embodiments, the filtration assembly 340 can be immediately downstream of the RPU 204. The filtration assembly 340 can include at least one fluid filter 342.

As further shown in FIG. 3, an outlet manifold 344 can be provided for fluid of the liquid cooling circuit to exit the LACU 200. The fluid exiting the outlet manifold 344 can be at a lower temperature than the fluid flowing into the LACU 200 at the inlet manifold 302. The description of the inlet manifold 302 can be applicable to the outlet manifold as well, and both manifolds 302, 344 can meet the description of the manifold 1300 shown and described with respect to FIG. 13.

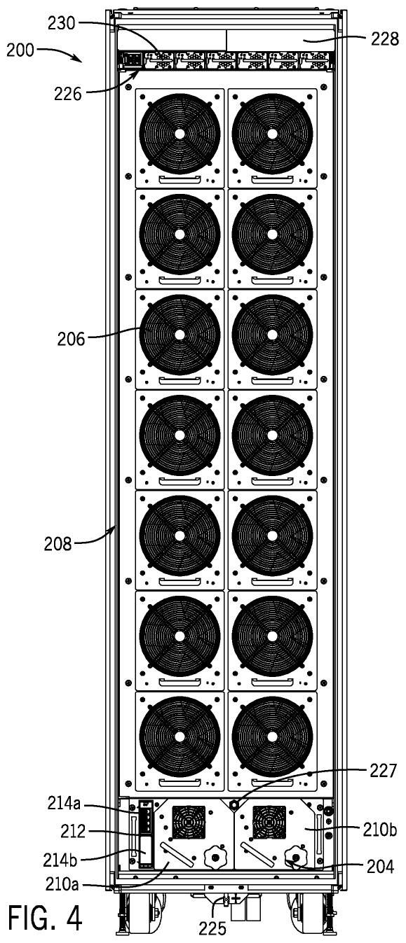

Connections for electricity can be provided within a data center to power electrical elements within cabinets installed in the data center. In some cases, redundant power supplies can be provided for a cabinet to ensure continued operation of the electrical components within a cabinet on failure of a single power supply. In this regard, FIG. 3 illustrates power inlets 350 to receive respective power connections from a data center. The power inlets 350 can be in direct electrical communication with the power supply unit 226 and the power supply modules 230 (shown in FIG. 2) can operate to transform the received power to have desired characteristics (e.g., to convert from AC to DC, to produce a desired output voltage or current, etc.). In some cases, the power inlets can receive a three-phase AC power signal. In some cases, a LACU 200 can operate with power from only one of the power inlets 350, and the opposite inlet can be used when there is a failure in the power source connected to the primary power inlet 350, or when the connection to the primary power inlet 350 is removed. In some cases, a first one of the power inlets 350 provides powers to a first plurality of power supply modules (e.g., three out of six of the power supply modules 230 illustrated in FIGS. 2 and 4) and a second one of the power inlets provides power to a second plurality of power supply modules (e.g., another three of the six power supply modules 230 shown in FIGS. 2 and 4). In some cases, an operator of the LACU 200 can set a mode in which to operate the LACU 200, which can include a power supply configuration including whether the power inlets 350 are used in a primary/backup configuration, whether the power inlets 350 each power a corresponding one or more power supply modules 230, or other configurable settings of a power supply unit.

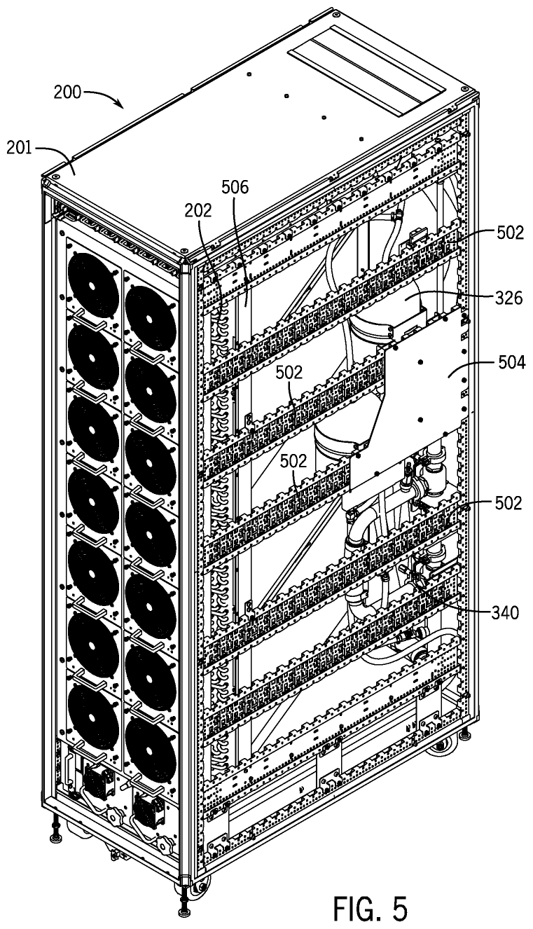

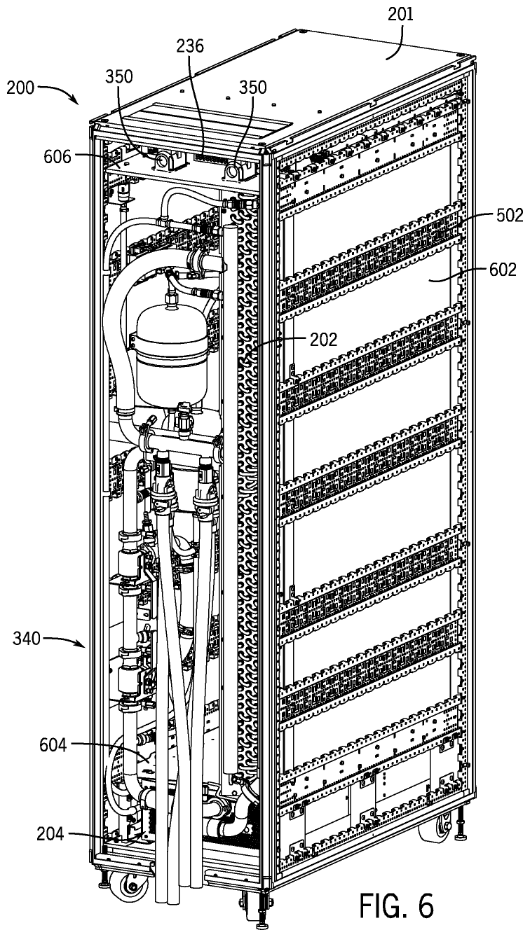

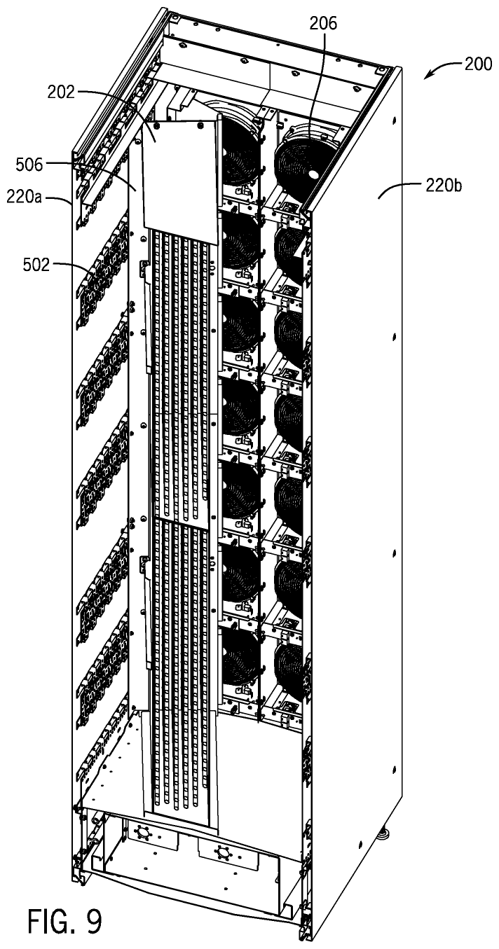

A cabinet of a liquid-to-air cooling unit can include structural components for mounting elements of the liquid-to-air cooling unit within the cabinet. For example, FIGS. 5 and 6 show the liquid-to-air cooling unit 200 with the side panels 220 removed to illustrate structural components of the cabinet 201. As shown, a plurality of mounting bars 502 can be provided that can span the cabinet 201 from a front to a rear of the cabinet 201. These mounting bars 502 can be spaced apart from each other in a vertical direction. As shown, plumbing components (e.g., the LAHX 202, filtration assembly 340, and expansion tanks 326) can be secured to the cabinet 201 at one or more of the mounting bars 502. For example, as shown in FIG. 5, an expansion tank mounting plate 504 is shown mounted to the mounting bars 502 of the cabinet 201. As shown, the expansion tank mounting plate 504 is secured to two contiguous mounting bars 502, which can provide greater stability to the system. Correspondingly, in some embodiments a filter mounting plate can be provided to mount the filter assembly 340 to the mounting bars 502 of the system. A vertical bracket 506 can be secured to a plurality of mounting bars 502 and can secure the LAHX 202 to the cabinet 201, as further described with respect to FIG. 9.

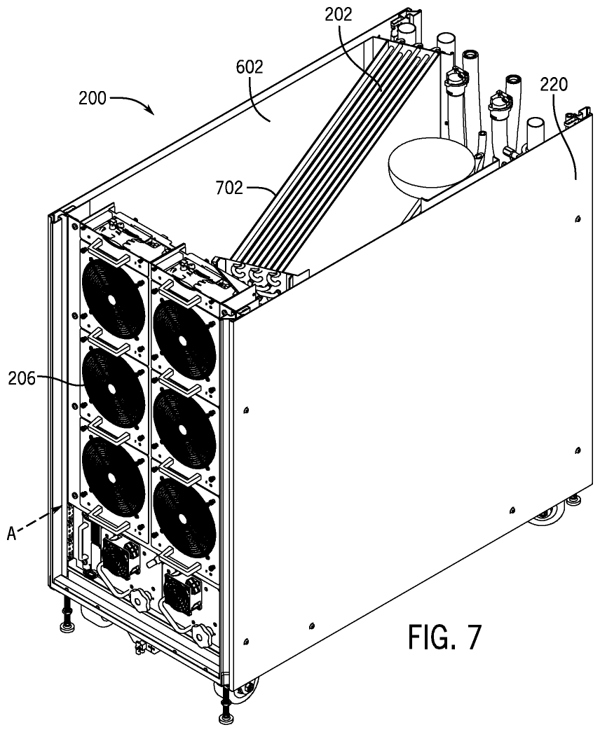

In some cases, a liquid-to-air cooling unit can include elements for directing air flow to maximize a heat transfer efficiency across a liquid-to-air heat exchanger. For example, as shown in FIG. 6, a baffle plate 602 can be provided on at least one side of the cabinet 201 of the LACU 200. The baffle plate 602 can prevent air flow out of the side of the cabinet before the air flow traverses the LAHX 202, thus increasing the cooling efficiency of the system by maximizing the flow of air through the LAHX 202. In some embodiments, baffle plates can be provided on both sides of a liquid-to-air cooling unit, or on either side of a liquid-to-air cooling unit. For example, it can be advantageous to maximize the flow of cool air across a heat exchanger, while it can be less important to control the flow of air once it has transferred heat from a liquid within the liquid-to-air heat exchanger. Thus, a direction of air flow across the heat exchanger can be relevant to determining a location or number of baffle plates of a liquid-to-air cooling unit. For example, as shown in FIG. 7, fans 206 of the LACU 200 can operate to produce an air flow in the A direction as shown, from the front of the LACU 200 to the rear of the LACU 200. The baffle plate 602 and the LAHX 202 can define a flow path of the air, with the baffle plate 602 preventing an air flow out of the side of the cabinet 201 shown. Substantially all air flow can be directed across a surface of the LAHX 202 to maximize a rate of heat transfer and an efficiency of a heat transfer (e.g., to reduce a power required for the fans 206 to produce a given heat transfer rate). In other embodiments, fans can direct air flow in a direction opposite direction A (e.g., from a rear to a front of the LACU 200), and it can be advantageous to position a baffle plate along the opposite lateral side of the LACU 200, to direct a maximal volume of cool air across the LAHX 202. In some cases, side panels (e.g., side panels 220 of LACU 200) can function as a baffle for air flow, and in some embodiments, a liquid-to-air heat exchanger may not include baffle plates.

In some cases, a liquid-to-air heat exchanger can be sized and positioned to maximize air flow through the heat exchanger. For example, a rate of heat transfer from a liquid to an air along a liquid-to-air heat exchanger can be increased by increasing a surface area of the heat exchanger. Increasing a surface area of a liquid-to-air heat exchanger can include maximizing a surface area exposed to air flow by positioning a heat exchanger at an oblique angle relative to a direction of air flow. IA surface area of a heat exchanger can be minimal when a heat exchange surface of a heat exchanger is perpendicular to a flow of air. As shown in FIG. 8 the LAHX 202 can be positioned along an axis B. The axis B can be positioned at an oblique angle C relative to a first side panel 220a at a first lateral side of the LACU 200. In the illustrated embodiment, the angle C is about 22.5 degrees. In some embodiments, an angle between a heat exchanger and a side panel of a liquid-to-air heat exchanger can be between 20-30 degrees, between about 30-40 degrees, between about 40-50 degrees, or up to 90 degrees. In some cases, an angle of a heat exchanger relative to a side panel can decrease with an increased depth of a liquid-to-air cooling unit. As also shown in FIG. 6, for example, the LAHX 202 can also span a height within the cabinet 201, between a plate 604 on a top of the RPU 204, and a plate 606 at a lower end of the power supply unit 236. In other embodiments, a heat exchanger can span other heights within a cooling unit, including, for example, when an RPU occupies a greater height (e.g., 8U).

Brackets for securing a heat exchanger within a cabinet of a cooling unit can be used to install heat exchangers at different points along a heat exchanger. In some examples, a bracket for a heat exchanger can be a sheet metal bracket and can be bent to accommodate different mounting angles (e.g., angle C) of the heat exchanger relative to side panels of the cooling unit. For example, as further illustrated in FIG. 8, a first mounting bracket 506a can secure the LAHX 202 to the cabinet 201 at a lateral side of the LACU 200 including a first lateral side panel 220a, and a second mounting bracket 506b can secure the LAHX 202 to the cabinet 201 at a second lateral side of the LACU 200 corresponding to a second lateral side panel 220b. Depending on a width of a heat exchanger, the heat exchanger can be mounted at different locations along respective lateral sides, and the mounting brackets 506a, 506b can deform to secure a heat exchanger at a desired angle within the cabinet 201.

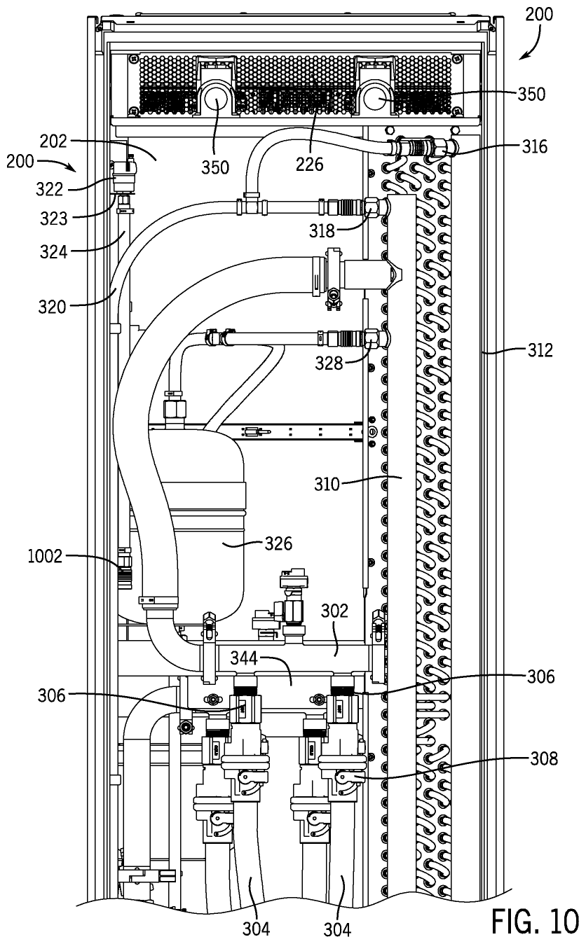

FIG. 10 is a partial rear view of the LACU 200, illustrating components housed in a top portion of the LACU 200. As described above, the LACU 200 can include the air bleed valve 322, which can be fluidly isolated from the fluid cooling circuit in normal operation of the LACU 200. As shown, the air-bleed valve 322 can be secured to the cabinet 201 (e.g., secured to a mounting bar 502 as shown in FIG. 5) via a mounting bracket 323. As shown, the hose 324 can extend downwardly (e.g., can hang from the bracket 323, and can include a quick connect fitting 1002 at the end of the hose. The quick connect fitting 1002 can be a female quick connect fitting and can be connected to either of the liquid ports 316, 318. For example, when bleeding air along the liquid cooling circuit, one or more of the connections from fill/drain hose 320 can be disconnected from the respective liquid port 316, 318, and the quick connect fitting 1002 of the air bleed valve 322 can be connected to the respective liquid port 316, 318 to bleed air therefrom. In some embodiments, an air bleed valve can be fluidly connected to the liquid cooling circuit during an operation thereof and can operate to continually bleed air from hosing thereof.

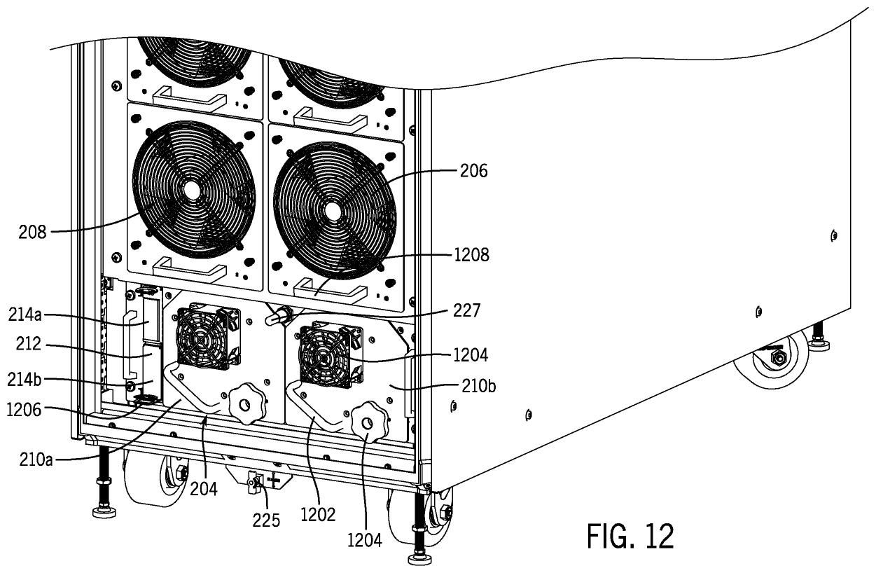

As discussed above, components of a liquid-to-air cooling unit can be redundant and hot-swappable, which can minimize a disruption to the operation of the cooling unit when a single component fails. Accordingly, hot-swappable elements of a cooling unit can include features to facilitate insertion and removal of the respective components. For example, FIG. 12 is a partial front isometric view of the LACU 1200, illustrating mechanical features for facilitating insertion and removal of components of the LACU 200. For example, as shown, each of the pump cassettes 210a, 210b can include a cassette handle 1202 to provide an operator a gripping point for removing or installing the respective pump cassette into the RPU 204. In some examples, a pump cassette can include more than one handle, to provide gripping locations for two hands of an operator, for example. In some cases, cassettes of an RPU can include features for locking the cassette in place or unlocking the cassette to enable removal. As further shown in FIG. 12, each pump cassette 210a, 210b can include a locking knob 1204, which, when rotated in a first direction (e.g., clockwise) can engage a locking mechanism of the RPU to lock the respective cassette 210a, 210b in place within the RPU. The locking knob 1204 can be rotated in a second direction opposite the first direction (e.g., counterclockwise) to disengage the locking mechanism, and allow translation of the pump cassette 210a, 210b relative to the RPU 204. As further shown in FIG. 12, fans 206 of the LACU 200 can include fan handles 1208 to provide a gripping location to allow an operator to remove the respective fan 206.

As further shown in FIG. 12, the hot swappable control modules 214a, 214b can also include cassette support features to facilitate removal and installation of the respective control modules 214a, 214b. As shown, each control module 214a, 214b can include an engagement tab 1206. The engagement tab 1206 can provide a gripping location (e.g., a handle) for an operator to install or remove the respective control module 214a, 214b from the RPU 204. Additionally, the engagement tab 1206 can include retention features to secure the respective control module 214a, 214b in place within the RPU 204. For example, protrusions of the grasping tab (not shown) can snap ably engage geometries of the RPU 204 to retain the control module 214a, 214b in place once inserted. To disengage the protrusions from the RPU 204 and allow removal of the respective control module 214a, 214b, an operator can displace the respective engagement tab 1206 in a vertical direction (e.g., along a height of the LACU 200), and can subsequently pull the engagement tab 1210 to remove the control module 214a, 214b. In other embodiments, other retention mechanisms can be used to retain a control module in place.

FIG. 13 illustrates a manifold, which can be inlet manifold 302 or the outlet manifold 344 (e.g., a supply or return manifold), as illustrated in FIGS. 3 and 6. In the illustrated embodiment of FIGS. 13, the manifold 1300 is oriented in a downward direction, relative to the cabinet, as may allow hosing 1302 from the electrical equipment cabinets to be routed through a cutout in the bottom of the cabinet, or out through the cutout 224 in the side panel 220, as illustrated in FIG. 2. As shown, an elbow connection 1304 extends from the left of the manifold. For an inlet manifold (e.g., manifold 302 illustrated in FIG. 3), the elbow connection 1304 couples a hosing 1306 to the manifold that routes the coolant to the heat exchanger (e.g., the LAHX 202, illustrated in FIG. 3). When the manifold 1300 is an outlet (e.g., a supply) manifold, the elbow connection 1304 and hosing 1306 fluidly connect the manifold 1300 to a filter assembly of a liquid-to-air cooling unit (e.g., filer assembly 340 shown in FIG. 3). On the right side of the illustrated manifold 1300, (i.e., a right side relative to the drawing sheet), a cap 1308 is provided to prevent fluid flow out of the right end of the manifold 1300. Though the manifold 1300 is shown in an orientation with the hosing 1302 extending downwardly (e.g., in a bottom feed configuration), the manifold 1300 may be positioned so that the hosing 1302 can extend upwardly from the manifold. To reverse the orientation, the manifold 1300 can be removed from the bracket 1310 securing the manifold 1300 to a cabinet (e.g., the cabinet 201 shown in FIG. 3). The manifold 1300 may be rotated and reinstalled in the bracket 1310, with the side of the manifold 1300 previously shown at the right being positioned at the left, and the side of the manifold shown on the left being reinstalled on the right. So positioned, the cap 1308 can be repositioned to the opposite of the manifold 1300, and the elbow connection 1304 can be repositioned to the opposite side of the manifold. The hosing 306 can then extend downwardly, and the hosing 1302 can extend upwardly relative to a cabinet (e.g., the hosing can be in a top feed configuration for the cabinet 201 shown in FIG. 2).

It can be advantageous to measure one or more properties of fluid at a manifold, including an inlet and outlet manifold. For example, a first temperature at an inlet manifold can indicate a heat of fluid returning from electrical equipment, and a temperature measured at a second manifold can indicate a heat of fluid being supplied to cool the electrical equipment. A difference between the first temperature and the second temperature can indicate a total cooling efficiency of a cooling unit and can be provided to control systems of the unit (e.g., as described below) to allow components of the cooling unit to be controlled to achieve a desired value (e.g., a set point) for a differential temperature between the inlet and the outlet. As illustrated, then, the manifold 1300 can include a sensor module 1312 (e.g., similar or identical to sensor modules 307, 345 shown in FIG. 3) positioned along the flow path of a fluid in a liquid cooling circuit. In some examples, as described, the sensor module 1312 can include a temperature sensor. In some cases, the sensor module can additionally or alternatively measure other properties of a fluid in the liquid cooling circuit, including, for example, a flow rate, a pressure, a density, a chemical composition etc. In some embodiments, sensors can be provided along different points of a flow path of fluid in a liquid cooling circuit and can be inputs or target values for a control system of a cooling unit.

A filter assembly for a cooling unit can include features for providing redundancy of components of the filter assembly and indicating a need for servicing of components of the filter assembly. FIGS. 14 and 15, for example, further illustrate the filter assembly 340, according to some embodiments. As shown in FIG. 14, the filter assembly 340 can be secured to the cabinet 201 with sheet metal brackets 1402 fixed to mounting bars 502 of the cabinet 201. As shown, piping of the filter assembly 340 can define a primary flow path 1406 and a secondary flow path 1408. An inlet valve 1410 can define an entry for each of the primary flow path 1406 and the secondary flow path 1408. An outlet valve 1412 can define an exit for fluid from each of the primary flow path 1406 and the secondary flow path 1408. The valves 1410, 1412 can include handles 1414 to allow the valves to be moved between a respective first position, in which flow is allowed exclusively through the primary flow path 1406, a secondary position in which fluid flow is allowed exclusively through the secondary flow path 1408, and a third position in which fluid flow is not allowed through either of the primary or secondary flow paths 1406, 1408. In some embodiments, either or both of the valves 1410, 1412 can be electronically controlled (e.g., through linear actuators, servo motors, etc.), and do not require manual engagement. In some embodiments, the valves 1412, 1418 are ball valves. In some embodiment, the valves 1412, 1410 can be any known valve with the capability of routing fluid flow as described. In some cases, as shown, the primary flow path 1406 does not include bends (e.g., fluid flows in a straight line from valve 1410 to valve 1412), and the secondary flow path 1408 includes one or more bends 1415 in piping thereof. Thus, the secondary flow path 1408 can introduce a greater pressure drop for fluid, compared with the primary flow path 1406.

As further illustrated in FIGS. 14 and 15, the primary flow path 1406 can include a primary filter 342, and the secondary flow path can include a secondary fluid filter 1416 for removing particulate matter and impurities from a fluid along either of the respective flow paths 1406, 1408. In some cases, particulate matter can build up within one of the respective filters 342, 1416, and the filter must be removed for servicing. To service one of the filters 342, 1416, an operator can move the valves (e.g., via the handle 1414) to a position to allow fluid flow through the flow path 1406, 1408 not including the filter to be serviced. Fluid can then flow through the other filter 342, 1416 while the filter is being serviced, and thus a maintenance to a filter does not introduce a down time for the LACU 200.

In some cases, a filter assembly can include features for detecting a state of a filter (e.g., for indicating a need to service a filter). For example, when particulate matter builds up within a filter, flow of fluid through the filter can be restricted, and a pressure upstream of the filter can be greater than a pressure downstream of the filter. Thus, measuring a pressure upstream and downstream of a filter can allow a control system or an operator to determine a pressure drop across a filter, and when a pressure drop exceeds a threshold value, this can indicate a need to service the filter. In this regard, FIGS. 14 and 15 illustrate a differential pressure sensor 1430 provided along the fluid coolant circuit. The differential pressure sensor 1430 can measure a pressure difference between a fluid at an upstream port 1432 and a downstream port 1434. The upstream port 1432 can be located upstream of both of the primary flow path 1406 and the secondary flow path 1408, and the downstream port 1434 can be located downstream of both of the primary flow path 1406 and the secondary flow path 1408. In some embodiments, as illustrated, hosing 1436 can be connected to each of the upstream port 1432 and the downstream port 1434 with quick disconnect fittings, to facilitate a servicing and replacement of the differential pressure sensor 1430. Thus, the differential pressure sensor 1430 can be removed and reinstalled without the use of tools, and without providing a disruption or interruption to the system operation. The differential pressure sensor can be operatively connected to a control system of the LACU 200, and the control system can provide an indication to an operator (e.g., an alert, a message, a visual indication, etc.) that one or more of the filters 342, 1416 require servicing.

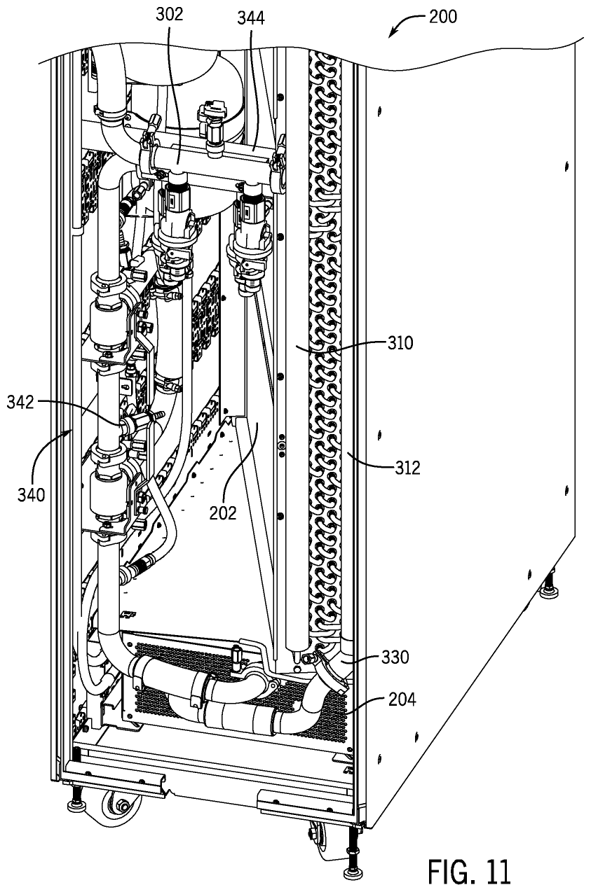

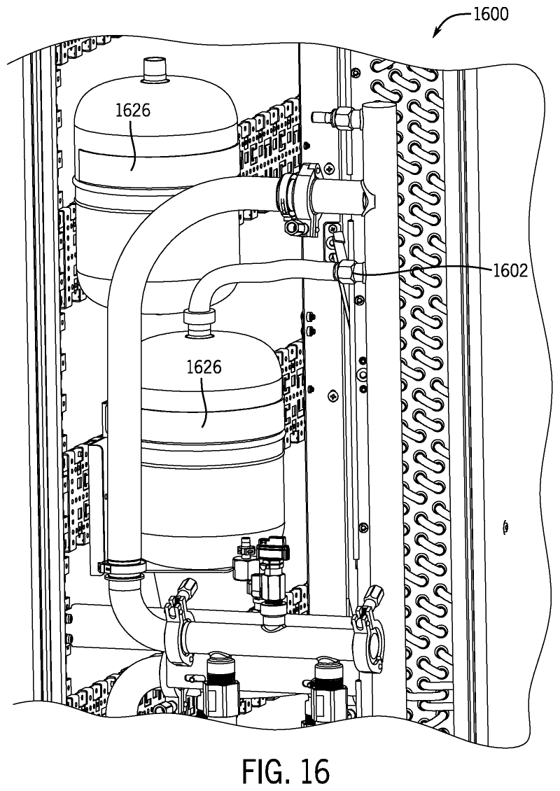

In some embodiments, pressure regulation systems of a liquid-to-air heat cooling unit can provide redundancy to the system and can be operated to allow a servicing or replacement of one pressure regulation system without causing a downtime to the unit. For example, FIG. 16 illustrates a LACU 1600 which can be substantially similar to LACU 200 illustrated in FIGS. 2-12. As shown, however, LACU include two expansion tanks 1626. The expansion tanks 1626 can each be charged for a rated pressure (e.g., 1 bar), and can be connected to plumbing of the LACU 1600 with quick disconnect fittings. Thus, one of the expansion tanks 1626 can be removed for servicing or replacement (e.g., by a toolless disconnection of the disconnect fitting from the tank 1626) and the other expansion tank 1626 can continue to regulate a pressure within the LACU 1600. In some embodiments, a LACU can include more than two expansion tanks, or only one expansion tank, or no expansion tanks. In some cases, only one of the expansion tanks 1626 is connected to the liquid cooling circuit at a given time, and an operator can manually connect a backup expansion tank 1626 to the liquid coolant circuit (e.g., at liquid port 1602), when the connection to the other expansion tan 1626 is removed.

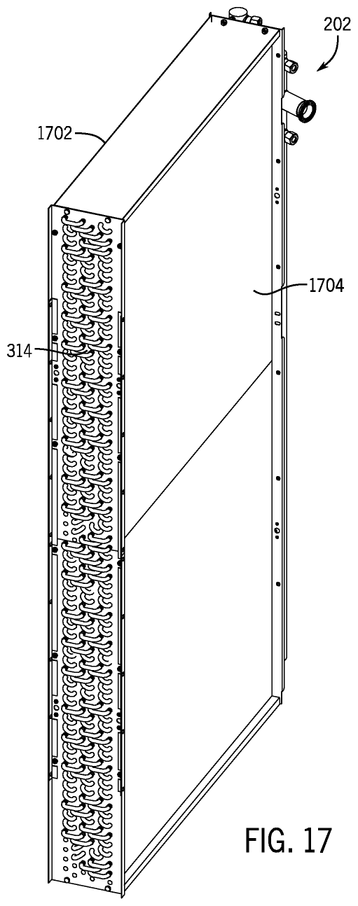

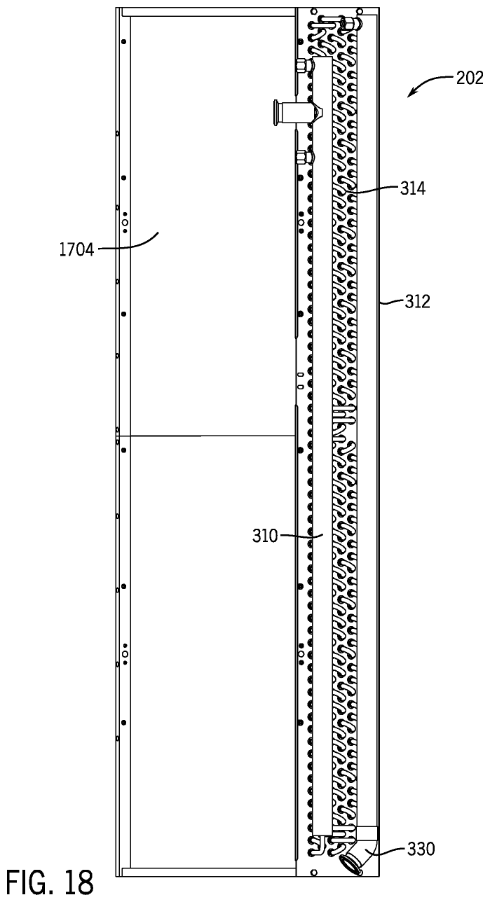

FIGS. 17 and 18 further illustrate the LAHX 202. The LAHX includes a front surface 1702 and rear surface 1704, which can each define a rectangular surface which, when installed, can span a width of the LACU 200, as described above. The area of these surfaces 1702, 1704 can provide an interface at which heat can be transferred from the liquid coils 314 within the LAHX 202 to the surrounding air. FIGS. 17 and 18 illustrate portions of the liquid cooling coils 314 protruding out from sides of the LAHX 202, and the combination of the total length of the coils 314, and the surface area of the coils 314 exposed to the surrounding air maximizes a cooling efficiency of the LAHX 202.

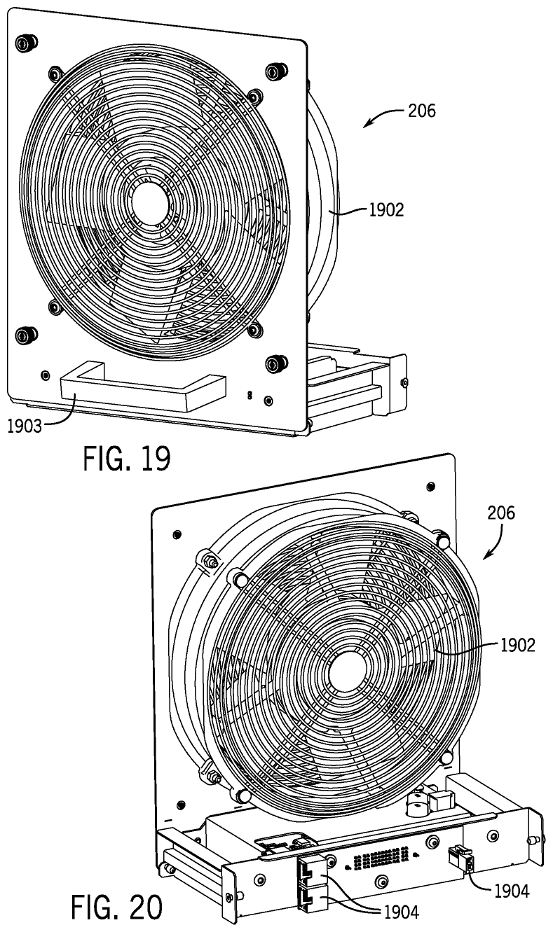

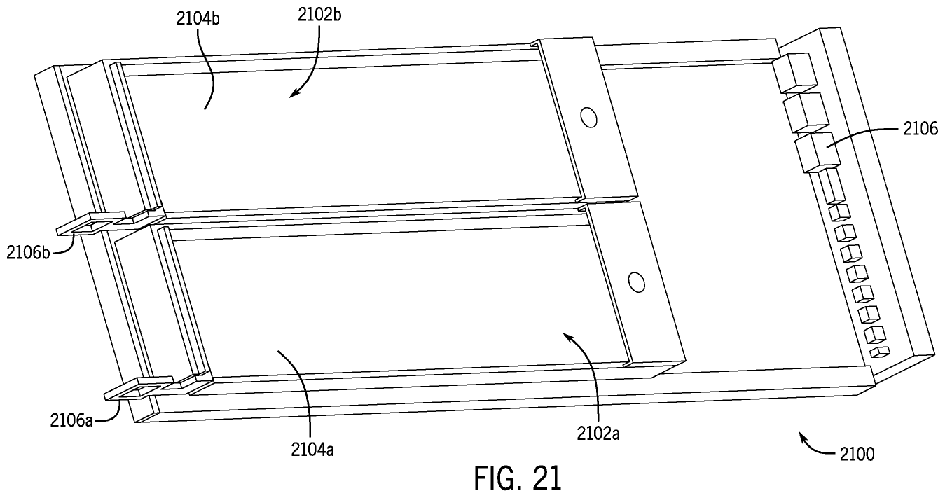

FIGS. 19 and 20 illustrate an embodiment of an individual fan module 1900. The fan module can 1900 can be substantially similar to (e.g., identical to) fans 206, shown in FIG. 2. As shown, the fan module 1900 can include an impeller 1902 mounted on a back side of the fan module 1900. The fan modules 1900 can include a handle (e.g., as described with respect to handle 1208 shown in FIG. 12) to facilitate insertion and removal of the fan module 1900 into a liquid-to-air cooling unit (e.g., LACU 200 illustrated in FIG. 2-12). The fan module 1900 can also include one or more blind mate connectors 1904 to engage corresponding electrical connections and interfaces of a LACU. The fan module 1900 can be a hot swappable fan module and can be replaced during operation of a LACU. In some cases, the fan module includes sensors (not shown) for sensing properties of an air flowing through the fan, or of an ambient air. For example, a fan module can include flow sensors to measure a rate of flow of air, temperature sensors, and/or humidity sensors. Additionally, a fan module can include a fan controller to control operating aspects of the fan (e.g., a fan speed). A controller of the fan can receive instructions from a main controller of a cooling unit (e.g., over a wired or wireless connection, a Modbus, ethernet, etc.). When a controller of a fan is not connected to a main controller, the fan controller can operate the fan according to preprogrammed algorithms to retain a speed, increase a speed, decrease a speed, or stop the impeller of the fan.

FIG. 21 illustrates a control unit 2100 for use in a LACU (e.g., similar or identical to the control unit 212 of the LACU 200, as shown in FIGS. 2 and 12). As shown, the control unit 2100 can include two compartments 2102a, 2102b for housing two separate control module 2104a, 2104b (e.g., similar or identical to control modules 214a, 214b shown in FIGS. 2 and 12), which can alternately be referred to as controller cartridges. The control unit can 2100 can be sized and configured to be received into a slot of an RPU (e.g., RPU 204 illustrated in FIGS. 2 and 12). Control modules 2104a, 2104b can include blind mate connecter (not shown), which can engage with corresponding electrical connections of an RPU when the control unit 2100 is installed therein. In some embodiments, the control modules 2104a, 2104b are identical, and can provide identical controls for a LACU. In some embodiments, electronic components of a LACU (e.g., fans 206 and RPU 204 illustrated in FIG. 2) can be controlled by one of the control modules 2104a, 2104b. In some embodiments, the control modules 2104a, 2104b include failover capabilities, so that when a primary one of the control modules 2104a, 2104b is removed from the control unit 2100, the other one of the control modules 2104a, 2104b assumes control of electrical components of the LACU. In some embodiments, a state of the system can be continually synced between the control modules 2104a, 2104b to facilitate failover when one of the control modules 2104a, 2104b fails or is replaced. In some example, each control module 2104a, 2104b can provide a different mode of operation or different control logic for the LACU, and the provision of two controller units can allow a user to selectively choose a particular control module 2104a, 2104b to use when the control unit 2100 is provided in the system. Alternatively, in some embodiments, one controller of the control module may provide a base functionality with the controller in the other compartment providing extension of functionalities for specific applications or embodiments of the sidecar unit. As shown, an interface board 2106 for inputs and outputs can also be provided in the control unit 2100 for connection to power, fans, pumps, and sensors. These interfaces can connect the controllers of the respective control modules 2104a, 2104b to the pump and fans of the liquid-to-air cooling unit (i.e., the sidecar unit), and the controller can adjust a speed of the fans or of a motor of the pumps in response to system parameters, as described further below.

A power supply unit (e.g., power supply unit 226 shown in FIG. 2) can be provided for a LACU to provide power to electronic components of the LACU at specific voltages, and with specific power characteristic (e.g., frequency, current, voltage, etc.). FIG. 22 illustrates the power supply unit 226 installed in a top of the LACU 200, and FIG. 23 illustrates the power supply unit 226. The power supply unit can include features and systems for providing redundancy and resiliency to a LACU, or other cabinets with electronic equipment which may be powered thereby. For example, as shown, the power supply unit 226 includes a plurality (e.g., 6) of hot-swappable power supply modules 230a, 230b, 230c, 230d, 230e. In some cases, each power supply module 230 can be a 3 kW power supply module. In other embodiments, power supply modules can provide about 1 kW, 2 kW, 4 kW, or 5 kW of power.

In some examples, a LACU (e.g., LACU 200 illustrated in FIGS. 2-12) can operate with a threshold number of power supply modules in operation. For example, a LACU can require a minimum of one power supply module, a minimum of two operational power supply modules, a minimum of three operational supply modules, a minimum of four operational supply modules, a minimum of five operational supply modules, etc. Thus, a system, including LACU 200 illustrated in FIGS. 2-12, can withstand the loss of one or more power supply modules 230 without stopping an operation of the LACU 200, as long as the number of operational power supply modules 230 exceeds a minimum threshold. As shown, each power supply module 230 can include a handle 2304 which can facilitate easy removal and installation of the power supply module 230 within the power supply unit 226. As further shown, a controller module 2302 can be provided in a power supply unit and can provide interfaces for wired connections into the power supply unit (e.g., ethernet connections, USB connections, etc.). In some cases, the controller module 2302 can include a controller for controlling an operating mode for power supply modules 230 of the power supply unit and can provide interfaces to allow a user to set an operating mode of the power supply unit 226.

In some cases, each power supply module of a power supply unit can be connected to (e.g., can receive power from) each power inlet of a pair of redundant power inlets (e.g., inlets 350, shown in FIG. 10). For example, all of power supply modules 230a, 230b, 230c, 230d, 230e, 230f can be connected to both a first power inlet and a second power inlet (e.g., inlets 350, shown in FIG. 10). In some cases, the first power supply can be prioritized, so that each of the power supply modules 230a-f receive power from the first power inlet while the first power supply is available, and only receive power from the second power inlet when the first power inlet is unavailable. In some examples, individual power supply modules can prioritize different power inlets to be used as a primary power inlet for the power supply module. For example, power supply modules 230a-f can each be connected to a first power inlet and a second power inlet, and power supply modules 230a, 230b, 230c can prioritize power from the first power inlet, while power supply modules 230d, 230e, 230f can prioritize power supplied by the second power inlet. In this configuration, if either of the first power inlet or the second power inlet fails or is disconnected, all of the power supply modules can receive a power from the other (e.g., the operational) power inlet. In some cases, three-phase power is received at the power inlets (e.g., power inlets 350 shown in FIG. 10), and power supply modules can filter a signal received from an inlet to process only a single phase of AC power from a given power inlet. For example, power supply module 230a can be connected to a first phase of AC power from a first power inlet, power supply module 230b can be connected to a second phase of AC power from the first power inlet, and power supply module 230c can be connected to a third phase of AC power from the first power inlet. In some cases, phases of AC power can be balanced across power supply modules of a power supply unit. In some cases, each power supply unit can convert an AC power received from an inlet into a DC power for powering components of a cooling unit (e.g., the LACU 200, shown in FIG. 2). Other configurations are possible, and power supply units can include more than 6 power supply modules or less than 6 power supply modules. Further, in some cases, a liquid-to-air cooling unit can include more than one power supply unit.

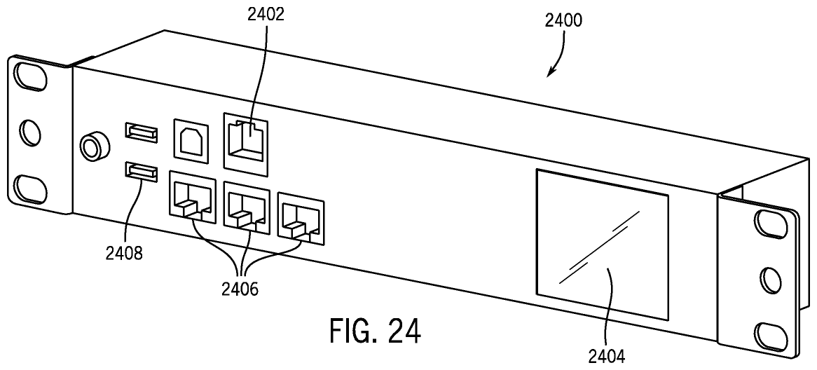

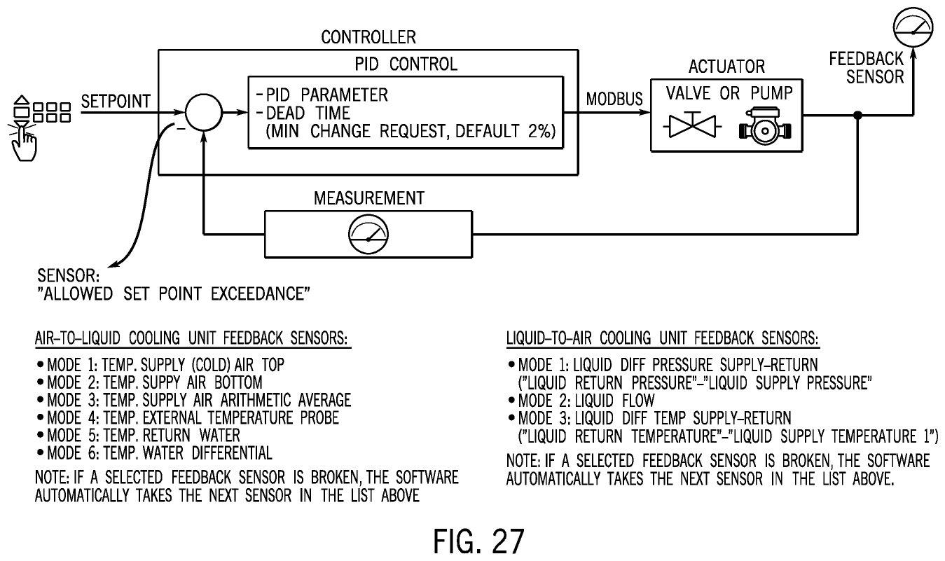

FIG. 24 illustrates an interface board 2400 for use with a liquid-to-air cooling unit according to embodiments of the invention. The interface board 2400 can include connections for sensors of a liquid-to-air cooling unit (e.g., sensors of the sensor list in FIGS. 27A and 27B). The board can have a 1 Gbe network interface 2402 for connecting to other components within the datacenter, and a user can access the interface through an LCD output 2404 provided on the unit, or through a web interface. In addition to the ethernet connection 2402 described above, the interface board can have ports 2406 for receiving sensor data, including analog or digital data. The board 2400 can provide monitoring capabilities for monitoring sensor values against set values and can provide alerting when the sensor values fall outside of a safe operating region defined in the system. As illustrated, the interface provides three sensor management ports 2406, with each port 2406 being capable of monitoring up to 16 sensor devices. A total length of cable connected to each port can be 40 meters, for example. The interface board can support multiple industry standard protocols for communication and alerting, e.g., SNMP, SMTP, HTTPS, BACnet, Modbus/TCP, and HPI. The interface board can include USB ports 2408 and analog and digital input ports to directly read sensors, for example, sensors with an output of 10 volts. Besides monitoring physical parameters like temperature, humidity, smoke, door status or water intrusion, the management gateway can also monitor in rack chillers and in row coolers with a plug and play installation. Set-up of the management gateway with security features, sensor configuration, user management, alarm and log management can be done through a built in Web Interface. Main access to the interface board 2400 is through the 1 GBE Network interface, supporting industry standard protocols like SNMP, SMTP, HTTPS, BACnet, Modbus/TCP and HPI.

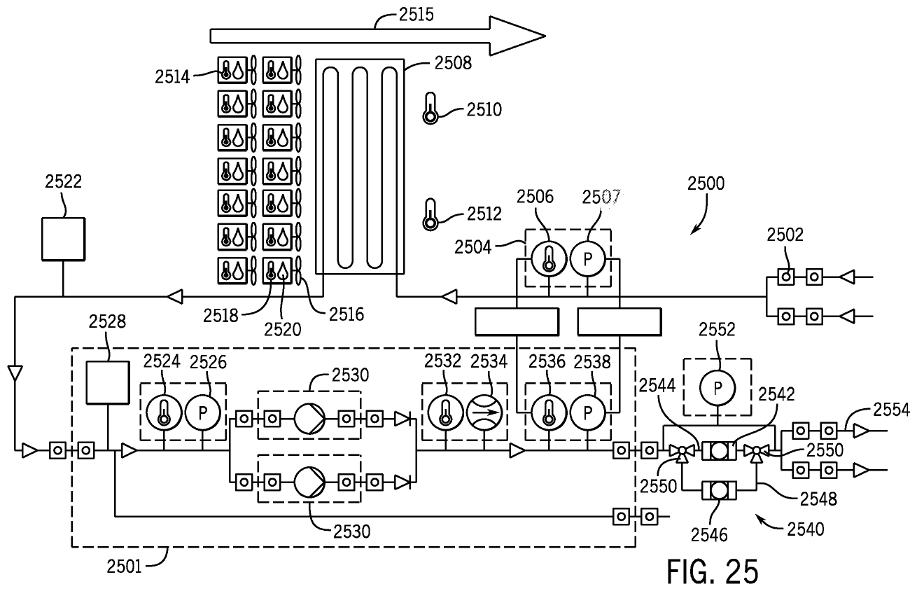

FIG. 25 is a system diagram for a liquid-to-air cooling unit 2500 that includes an RPU 2501 to provide closed loop circulation when coupled to a server unit or other electrical components to be cooled. The liquid-to-air cooling unit 2500 can be substantially similar to (e.g., identical to) the LACU 200 described above and illustrated in FIGS. 2-12. The system includes a liquid return line manifold 2502 (e.g., an inlet, similar to the inlet manifold 302 shown in FIG. 3) with a first sensor module 2504 including a temperature liquid return sensor 2506 and a pressure liquid return sensor 2507. In some embodiments, the first sensor module 2504 is positioned on the inlet manifold 2502 (e.g., the first sensor module can be included in sensor 1312 mounted to manifold 1300, shown in FIG. 13). In other embodiments, a sensor module for sensing properties of a liquid along a return can be positioned at any point in a LACU fluidly upstream of a heat exchanger of the LACU. The return liquid enters a LAHX 2508 (e.g., similar to LAHX 202 illustrated in FIG. 3) which can include a top air temperature sensor 2510 to measure a temperature of an air along a top of the LAHX 2508, and a bottom air temperature sensor 2512 to measure a temperature of an air along a bottom of the LAHX 2508.

The LACU 2500 can include a plurality of fan modules 2514 (e.g., fans 206 illustrated in FIG. 2), which, in the illustrated embodiment, includes 14 fan modules 2514, each including a single fan. In some embodiments, a LACU can include more fan modules or fewer fan module. Some embodiments can include fan modules with one, two, or four fans. Each of the fan modules 2514 placed adjacent to the LAHX 2508 can include three sensors, including a fan speed sensor 2516, an air temperature sensor 2518, and an air humidity sensor 2520. The fan modules 2414 can produce an air flow 2515 across the LAHX 2508 to cool a liquid flowing through the LAHX 2508. Cooled liquid flowing out of the LAHX 2508. can pass toward the RPU 2501 past one or more external bladder expansion tanks 2522 that accommodate any thermal expansion of air, liquid, or fluids in the system. Properties of the liquid entering the RPU 2501 are sensed by a RPU suction temperature sensor 2524 and an RPU suction pressure sensor 2526. In some cases, as illustrated, the RPU 2501 can include an internal bladder expansion tank 2528 to accommodate any thermal expansion of air, liquid, or fluids in the RPU 2501. The liquid of the system passes through one or both of a pair of pump cassettes 2530 in the RPU 2501. In some embodiments, pump cassettes (e.g., the pump cassettes 2530) can each include a pump speed sensor. The liquid can exit the pump cassettes 2530 and flows past additional sensor modules, including a supply liquid temperature sensor 2532, a liquid supply flow rate sensor 2534. A second sensor module 2535 can be positioned downstream of the pump cassettes 2530, and can include a liquid temperature sensor 2536, and a liquid pressure sensor 2538. In some cases, a differential temperature can be calculated between a supply temperature of a liquid measured at fluid temperature sensor 2506 and a return temperature of liquid measured at liquid temperature sensor 2536. Similarly, a differential pressure can be calculated between a supply pressure measured at pressure sensor 2507 and a return pressure measured at 2538. While in the illustrated embodiment, the second sensor module 2535 is positioned in the RPU, in other embodiments, it can be advantageous to position a return sensor module (e.g., the second sensor module 2535) at an outlet of a cabinet of an LACU (e.g., along manifold 2554 shown in FIG. 25). In some embodiments, a control system for the RPU 2501 is located onboard the RPU 2501. In some cases, a control module of the RPU 2501 can provide control signals to fan modules 2514 to control a rotation of fans thereof. In some cases, each pump cassette 2530 can include a local controller for controlling aspects of a corresponding pump of the pump cassette. Using the various sensors described herein, the control system can control a speed of pumps and/or the fans to achieve target values for cooling the fluid in the system.

The liquid can flow from the RPU 2501 through a filter assembly 2540 which can filter the fluid along either or both of a primary filter 2542 of a primary flow path 2544, or a secondary filter 2546 of a secondary flow path 2548. Valves 2550 (e.g., three-way valves) can be provided at an entry and exit of the primary and secondary flow paths, to selectively allow fluid through either or both of the primary flow path 2544 and the secondary flow path 2548 (e.g., as described with respect to FIGS. 14 and 15). A differential pressure sensor can 2552 can sense a differential pressure between a fluid upstream of the primary and secondary flow paths 2544, 2548, and a fluid downstream of the primary and secondary flow paths 2544, 2548. A differential pressure sensed by the differential pressure sensor 2552 that is above a differential pressure threshold can indicate a need for servicing one or more of the filters 2542, 2546. Fluid can flow from the filter assembly 2540 to a return manifold 2554 to cool electrical equipment downstream of the LACU 2500.

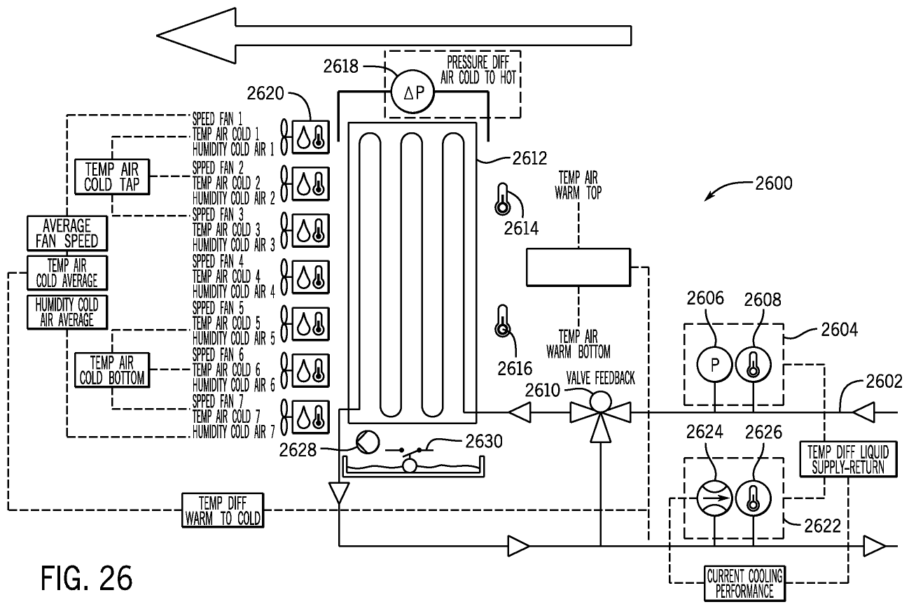

FIG. 26 is a system diagram for liquid to air heat cooling unit 2600 connected to a water supply, such as a pressurized water supply for a building. The system includes a liquid return line 2602 that passes a sensor module 2604 including a pressure liquid supply sensor 2606 and a temperature liquid supply sensor 2608. The liquid passes through a three-way motorized valve 2610 before entering the heat exchanger 2612 with a temperature air warm top sensor 2614 and a temperature air warm bottom sensor 2616. The heat exchanger further includes a pressure differential air cold to hot sensor 2618. The liquid to air heat exchanger 2612 can include seven fan modules 2620. Some embodiments can include fan modules with one, two, or four fans. Each of the fan modules 2620 placed adjacent to the heat exchanger 2612 can include three sensors, including a fan speed sensor, a temperature air cold sensor, and a humidity cold air sensor. The sensed parameters can be analyzed by a control system to calculate a number of parameters, such as temperature air cold top, average fan speed, temperature air cold average, humidity cold air average, temperature air cold bottom, and temperature differential warm to cold. The liquid exists the heat exchanger 2612 and flows past a final set of sensors 2622 including a liquid flow rate sensor 2624 and a temperature liquid return sensor 2626. Additional parameters can be calculated, including temperature differential supply-return and current cooling performance. The system can further include a condensate pump 2628, the state of which can be monitored by calculating the parameters noted above, the status of which can be controlled using a condensate level switch 2630.

In some cases, control systems and processes can be implemented by controller of a cooling system to achieve a desired cooling rate, maintain operating parameters of a cooling unit within threshold ranges, achieve a power efficiency, etc. For example, referring specifically to FIG. 25, a controller can provide signals to fans 2514 to increase a flow rate of air across the heat exchanger 2508 in order to achieve a target outlet temperature for fluid of the LACU 2500. Additionally or alternatively, a speed of one or more of the pumps 2530 can be adjusted to induce a target pressure or pressure difference in the system, or to achieve a target temperature or temperature differential for temperatures measured at different points along a liquid cooling circuit. In some cases, fans 2514 and pumps 2530 can be controlled independently to achieve different set points for operating parameters of the LACU 2500. In some cases, the fans 2514 and pumps 2530 can be controlled in coordination. In some cases, one of the pumps or fans can be controlled to operate at a set value (e.g., fan speed or pump speed), which is not changed to achieve a target for an operating parameter of the LACU.

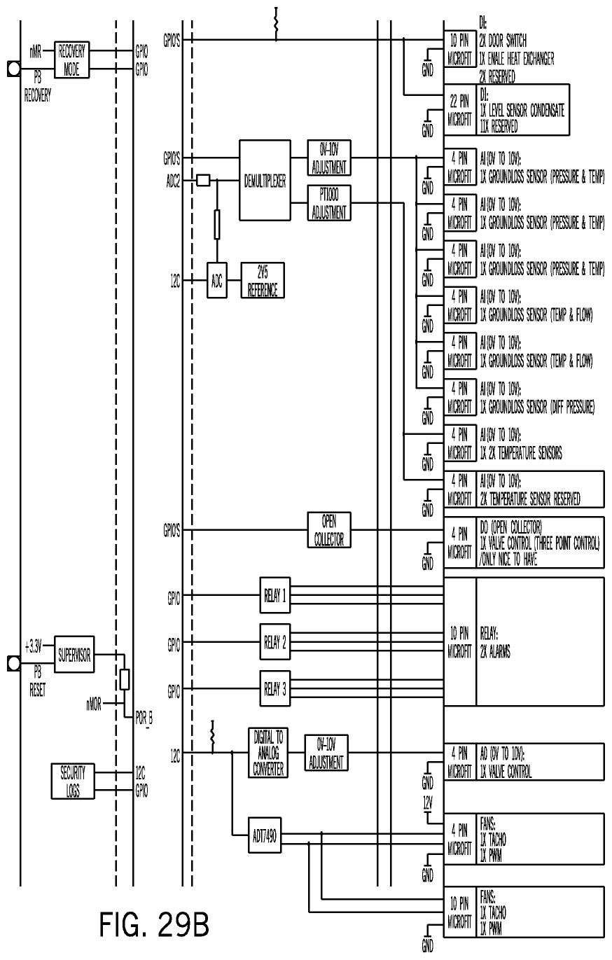

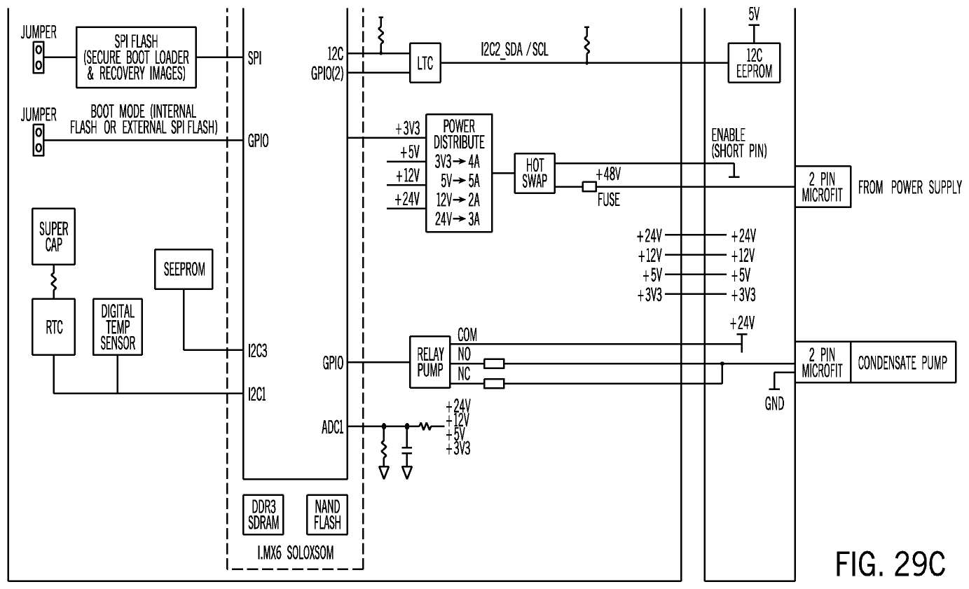

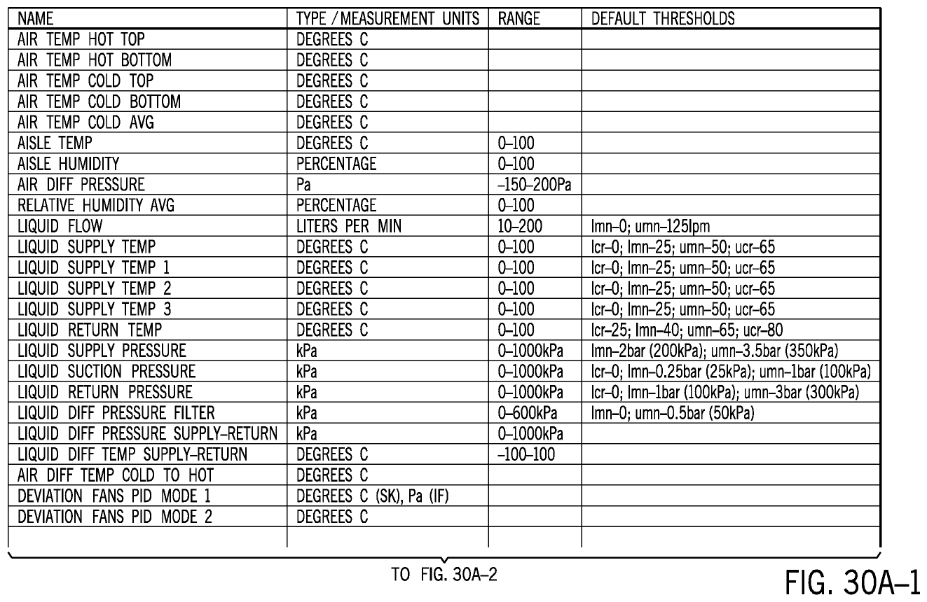

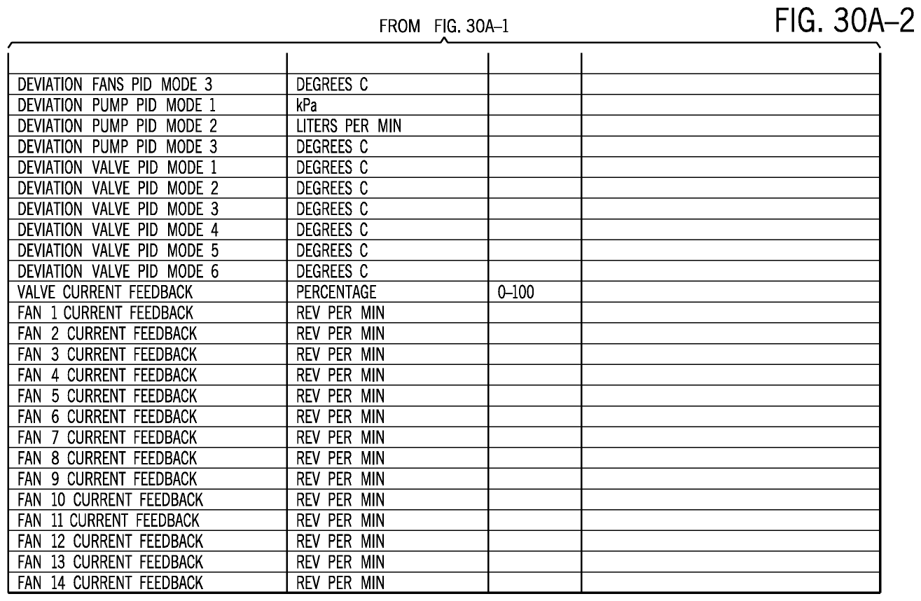

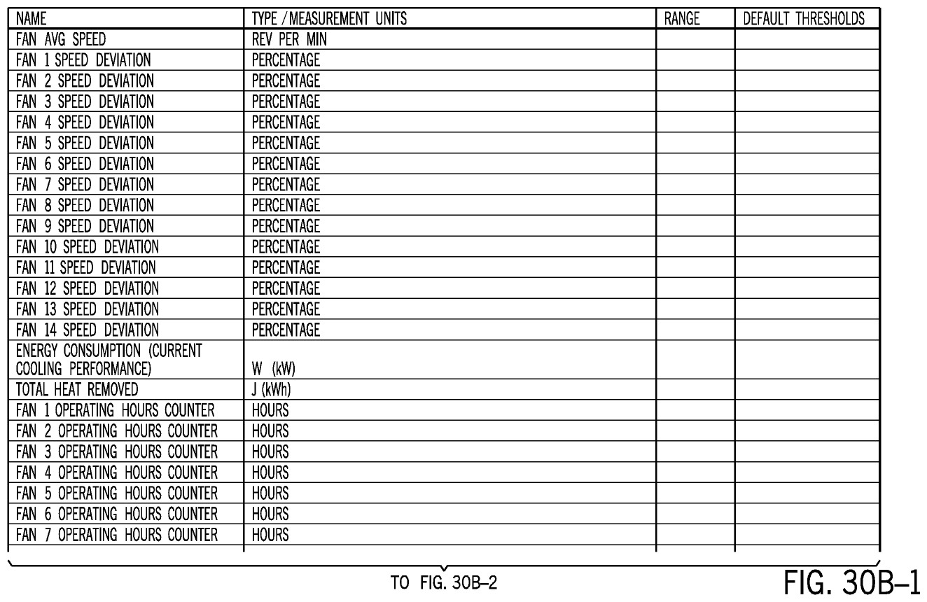

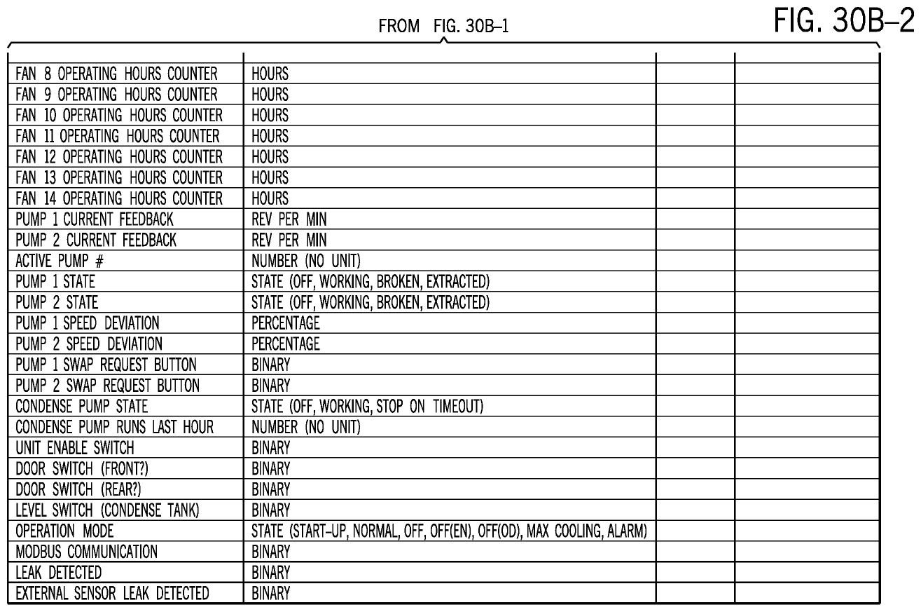

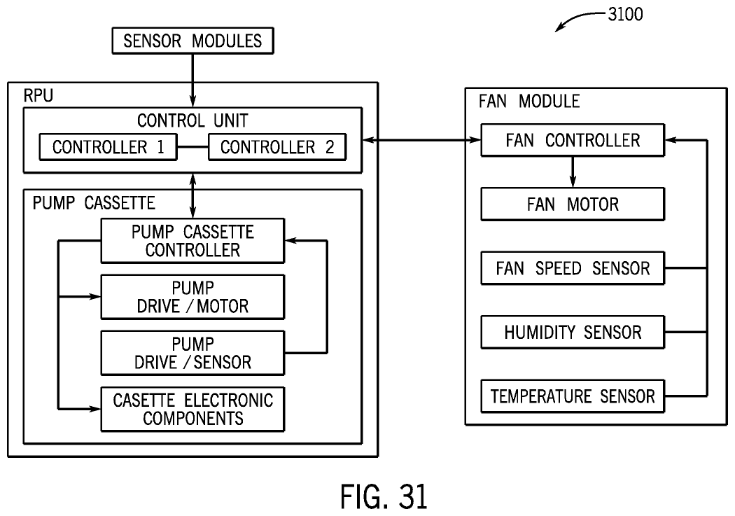

Actuators (e.g., fans 2514 and pumps 2530 of LACU 2500 shown in FIG. 25) can be controlled according to proportional integral derivative controls to achieve corresponding set points for operating parameters. For example, a controller (e.g., a controller of control modules 214a, 214b shown in FIGS. 2 and 12, the main controller illustrated in FIGS. 29A-29C or either of “Controller 1” or “Controller 2” of the “Control Unit” of system 3100 shown in FIG. 31) can have programmed thereon operating ranges for operating parameters of a LACU (e.g., as listed in FIGS. 30A-1 through 30B-2), set points for operating parameters, and gains of one or more PID controllers to be implemented by the controller. Operating parameters, set points, and gains can be preprogrammed at a memory of the controller, or can be set by a user at an input interface of the controller (e.g., a graphical user interface, a web interface, a command line interface, an ethernet interface, a Modbus interface, etc.). The controller can implement a PID control to vary an input into an actuator (e.g., a pump as shown, which can be one or more pumps housed in cassettes 210a, 210b shown in FIG. 2, or pumps 2530 shown in FIG. 25) to achieve a set point (e.g., a target value) for a measurement of a value from a feedback sensor. A measurement from a feedback sensor can be provided back to the controller, which can determine, based on the measurement, an error relative to the desired set point, and can output a signal to the actuator to adjust an operation thereof (e.g., a pump speed). This process can be continuously implemented and can iteratively measure a value, compare that measurement to a set value (e.g., calculate an error), and generate a signal to an actuator to produce a desired output for the feedback sensor.

As further illustrated in FIG. 27, the PID control implemented by the controller can be used to operate one or more pumps as actuators (e.g., pumps 2530 shown in FIG. 25, or pump housed in cassettes 210a, 210b shown in FIG. 2). In some embodiments, the pumps can be operated according to one of three operating modes, as shown, with each operating mode corresponding to a give sensor or set of sensors of the system. For example, in mode 1, as shown, the pumps can be operated to achieve a target value for a differential pressure between a supply and return of a liquid-to-air cooling unit (e.g., the inlet and the outlet of LACU 2500 shown in FIG. 25). With reference to FIG. 25, in mode one, a target value can be a difference between a pressure measured at pressure sensor 2507 (e.g., an inlet or return pressure) and a pressure measured at pressure sensor 2538 (e.g., an outlet or supply pressure). The controller can provide a signal (e.g., to variable frequency drives of one or more of the pumps) to increase a pump speed or decrease a pump speed to achieve the pressure differential. In some cases, mode 1 is a default mode of operation for a liquid-to-air cooling unit. In some cases, an operator (e.g., a user) can select a mode (e.g., including mode 1) in which to operate controls to control a pump speed of the system.

In some cases, a mode of a controller can at least partially depend on an operational state of one or more components of a liquid-to-air cooling unit (e.g., the LACU 200 illustrated in FIGS. 2-12, the LACU 2500 illustrated in FIG. 25, etc.). For example, if a feedback sensor for a given PID control or mode of a PID control is inoperational, or incommunicative with a controller, the controller can switch to another mode, to implement a PID control to achieve a set point for a different operating parameter of the cooling unit. For example, if one or both of sensors 2507, 2538 are inoperational, the controller may not be able to implement mode 1 as illustrated, and the controller may automatically switch to another mode of operation for implementing a PID control (e.g., mode 2 or 3). For example, the controller can switch to Mode 2 to control a speed of pumps 2530 to achieve a set value for liquid flow through the LACU 2500, as can be measured, for example, by flow rate sensor 2534. When neither of modes 1 or 2 are feasible, as when either or all of sensors 2507, 2538, 2534 are operational, the controller can implement a PID control according to mode 3, to achieve a differential temperature between an inlet and outlet (e.g., a return and supply) of the LACU 2500, as can be measured as a difference between temperatures received at temperature sensor 2506 and temperature sensor 2536 respectively. In some cases, either of modes 2 or 3 can be the primary or default mode, and a controller can switch to the other respective modes upon an unavailability (e.g., a failure or lack of communication with feedback sensors of the primary mode). In some cases, additional modes can be implemented to achieve set points for any measured value or differentials between measured values.

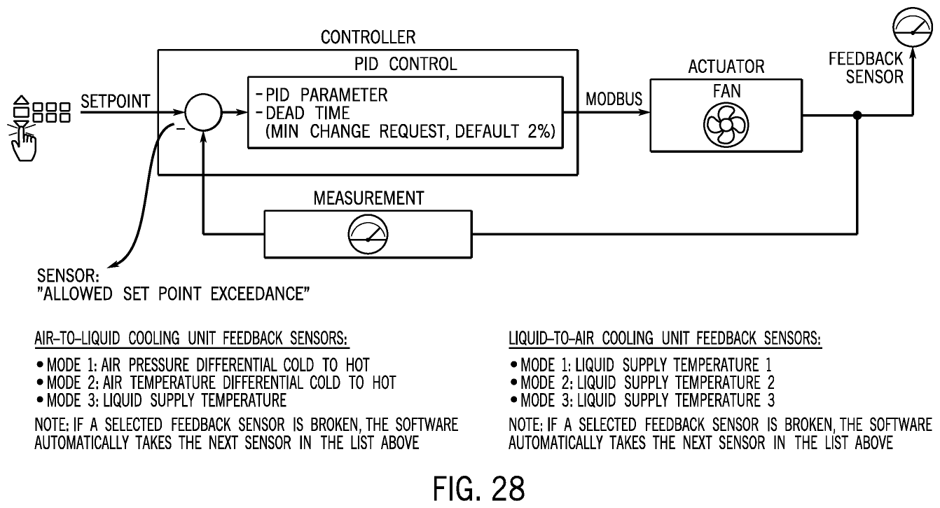

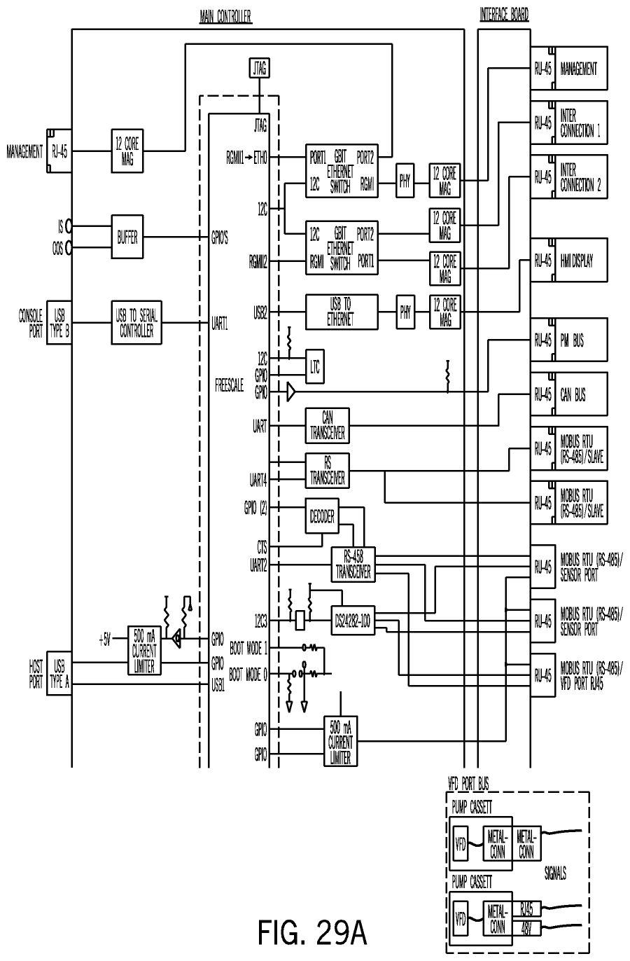

A controller for a liquid-to-air cooling unit (e.g., any or all of LACUS 100, 200, 1600, 2500) can implement PID controllers with components other than pumps as actuators. For example, FIG. 28 illustrates a feedback control system for any of the liquid-to-air cooling units 100, 200, 2500, or 2600 illustrated in FIGS. 1, 2-12, 25, and 26 respectively, wherein a controller for the respective LACU controls a speed of one or more fans of the LACU to achieve a set point for a value of a feedback sensor. The feedback control system shown in FIG. 28 can be implemented in addition to or alternatively to the feedback control system shown in FIG. 27. As shown, the fans (e.g., fans 206 as shown in FIG. 2, or fans 2514 shown in FIG. 25) can be controlled in any of modes 1-3 to achieve an output temperature for liquid of the liquid coolant circuit. For example, mode 1 can rely on temperature sensor 2536 as a feedback sensor, mode 2 can rely on temperature sensor 2532 as a feedback sensor, and mode 3 can relay on temperature sensor 2524 as a feedback sensor. The modes provided for either or both of the feedback control systems shown in FIGS. 27 and 28 are provided for illustration and are not intended to be limiting.

FIGS. 29A-29C illustrate an embodiment of a controller and an interface board connected to a controller, and the pump cassettes of an RPU (e.g., RPU 204 shown in FIG. 2), showing an electrical schematic for the controller's microprocessor including the various inputs into the microprocessor and the various outputs to the interface board and to the interface board's ports.

FIGS. 30A-1 through FIGS. 30B-2 list examples various sensors that can be included in the control system. Subsets of these sensors are used to monitor and control either the liquid-to-air cooling unit or the liquid to air heat exchanger. The sensors can be connected to a control system and supported for communication with the control system firmware. A smaller subset of the sensors can be used by the feedback control system, including those sensors shown in FIGS. 25 and 26 for use in the PID control loop. Many of the sensors are only informational, for example, to determine whether certain temperatures are too high or certain fan or pump speeds are too low. In some embodiments, active operation only relies on two sensors for the pump control loop and the fan control loop. Some of the sensors may be redundant so that if sensors malfunction, the system uses fallback sensors to continue operation.

FIG. 31 illustrate a control system 3100 for any or all of the LACUs 100, 200, 1600, or 2500 described above. The control system 3100 can be used to implement either or both of the feedback control systems shown in FIGS. 27 and 28, and the process 3300 shown in FIG. 33. As shown, the control system 3100 can include an RPU (e.g., RPU 104 shown in FIG. 1, RPU 204 shown in FIG. 2, RPU 2501 shown in FIG. 25), a Fan Module (e.g., one or more of the fans 106 shown in FIG. 1, fans 206 shown in FIG. 2, and fans 2514 shown in FIG. 25), a Sensing Modules. The sensing modules of the control system 3100 can include temperature sensors, pressure sensors, flow sensors, humidity sensors, or other know sensor types. For example, the Sensor Modules can include any or all of sensors 2506, 2507, 2510, 2512, 2518, 2520, 2516, 2524, 2526, 2532, 2534, 2536, 2538, and 2552 of LACU 2500 shown in FIG. 25. For purposes of illustration, only one Fan Module is shown, however, it is to be understood that the control system 3100 can include any number of fan modules and associated fans, including, for example, 14 fans, as shown and described with respect to FIGS. 2 and 25.

The RPU can include one or more Pump Cassettes and a Control Unit. While only one Pump Cassette is illustrated, an RPU can include distinct control components for multiple pump cassettes (e.g., 2 pump cassettes). The Control Unit can include two controllers: Controller 1 and Controller 2, which can be substantially identical, or can include different programing to implement different controls for one or more elements of a cooling unit. In an example, Controller 1 can be housed in the control module 214a of LACU 200, as shown in FIG. 12, and Controller 2 can be housed in control module 214b of LACU 200, as shown in FIG. 12. In some examples, controllers of a control unit (e.g., Controller 1 and Controller 2 of the illustrated Control Unit) can be operated in an active-passive mode, with only one of the controllers being active at a particular time. For example, Controller 1 can be configured as a primary controller and Controller 2 can be a secondary controller (e.g., a backup or standby controller) and Controller 2 switch to being the primary controller for the system in the case of a failure in Controller 1. In other embodiments, a control unit of a cooling system can include only one controller, or more than two controllers.

As illustrated, the Fan Module can include a Fan Controller, which can provide local controls for an individual fan module (e.g., as partially described with respect to FIGS. 19 and 20). The Fan Module can further include a Fan Speed Sensor (e.g., fan speed sensor 2516 shown in FIG. 25) a Humidity Sensor (e.g., humidity sensor 2520 shown in FIG. 25), and a Temperature Sensor (e.g., temperature sensor 2518 shown in FIG. 25). Each of the Fan Speed Sensor, Humidity Sensor, and Temperature Sensor can provide measurements for a sensed value to the Fan Controller. The Fan Module can further include a Fan Motor, as shown, which can receive a signal from the Fan Controller to drive an operation of the Fan Motor. As further shown, the Fan Controller can be in communication with the Control Unit. In normal operation of the control system 3100, the Fan Controller can provide sensed values from any of the described sensors to the Control Unit (e.g., to either or both of Controller 1 and Controller 2) and can receive a signal from the Control Unit to drive operation of the Fan Motor. In other cases, including when a communication between the Fan Module and the Control Unit is interrupted, the Fan Controller can autonomously control a speed of the Fan Motor, according to instructions preprogrammed in the Fan Controller. In some examples, when a fan controller is autonomously driving a fan motor, it can operate a feedback control system based on sensor parameters obtained from sensors of the fan module.

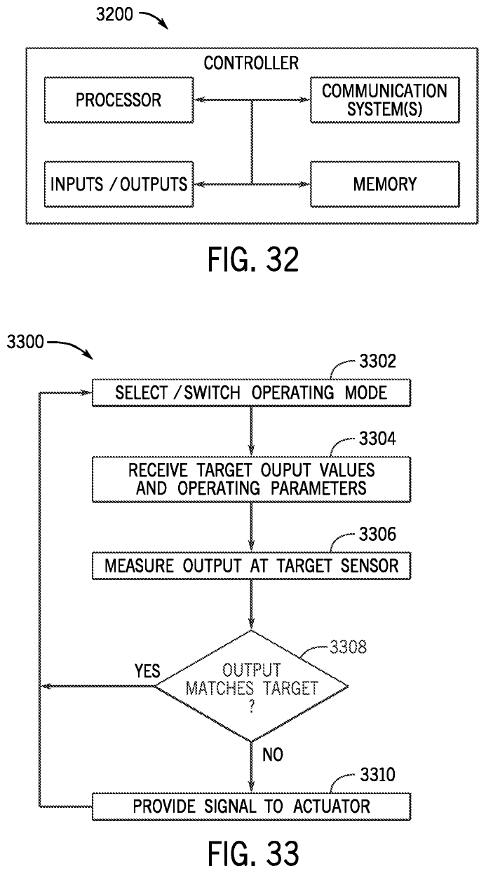

As further shown in FIG. 31, the Pump Cassette can include a Pump Cassette Controller, which can provide control signal for one or more of a Pump Drive/Motor (e.g., a motor of pump 2530 illustrated in FIG. 25) and Cassette Electronic Components (e.g., LEDs, fans, locking systems, servo motors, linear actuators, speakers, etc.). The Pump Cassette Controller can receive measured signals of a pump speed from a Pump Drive/Sensor, as shown. In some examples, a Pump Cassette can include additional sensing components to sense operational parameters of the Pump Cassette (e.g., signals from sensors 2524, 2526, 2532, 2534, 2536, 2538 housed in RPU 2501 shown in FIG. 25). The Pump Cassette Controller can be in communication with the Control Unit (e.g., via a wired or wireless connection), and can receive instructions from one or both of Controller 1 and Controller 2 to drive a speed the Pump Drive/Motor and/or control the Cassette Electronic Components. As described with respect to the Fan Controller, if communication is lost between the Control Unit and the Pump Cassette Controller, the Pump Cassette Controller can control elements of the Pump Cassette autonomously until a connection is restored with the Control Unit. In some examples, each of the Controller 1, Controller 2, the Pump Cassette Controller, and the Fan Controller can be an instance of the controller 3200 shown in FIG. 32, which is described below.

Referring back to FIG. 31, the Control Unit can be in communication with the Sensor Modules to receive sensed values from sensors thereof. The Control Unit can provide signals (e.g., instructions) to one or more of the Fan Controller and the Pump Cassette Controller to implement a feedback control system (e.g., as described in FIGS. 27 and 28) to achieve a set value for a sensor of the Sensor Modules. In some embodiments, a control unit can be in direct communication with sensors of fan modules and pump cassettes (e.g., the Control Unit can be directly connected to any or all of the Fan Speed Sensor, Humidity Sensor, Temperature Sensor, etc.).

In some examples, communication between components of the control system 3100 can be over a wired connection (e.g., a Modbus, an ethernet connection, USB connections, etc.). In some embodiments, communication between one or more elements of the control system can occur via a wireless connection (e.g., a wi-fi connection, a cellular connected, etc.).

FIG. 32 illustrates an example of a controller 3200 that can be used in a cooling system (e.g., LACU 100, 200, 1600, 2500). In some embodiments, the controller 3200 can be a programmable logic controller (PLC). In some embodiments, the controller 234 can include a processor, one or more Input/Output interfaces, a Communication System(s), and a Memory. In some embodiments, the Processor can be any suitable hardware processor or combination of processors, such as a central processing unit (CPU), a graphics processing unit (GPU), an application specific integrated circuit (ASIC), a field-programmable gate array (FPGA), etc. In some embodiments, one or more Input/Output interfaces can include any suitable display device, such as a computer monitor, a touchscreen, a television, any suitable input devices and/or sensors that can be used to receive user input, such as a keyboard, a mouse, a touchscreen, a microphone, a camera, etc. Inputs can be received at a display which can present a user interface through which an operator can view system parameters, and set control parameters (e.g., set an operating mode, define set points for temperature or pressure, set a language of the system, etc.).

In some embodiments, the Communication System(s) of the controller 3200 can include any suitable hardware, firmware, and/or software for communicating information over any suitable communication networks. For example, the Communication System(s) can include one or more transceivers, one or more communication chips and/or chip sets, etc. In a more particular example, the Communications System(s) can include hardware, firmware and/or software that can be used to establish a Wi-Fi connection, a Bluetooth connection, a cellular connection, an Ethernet connection, etc. In some embodiments, inputs can be received at the controller 3200 through the Communication System(s) (e.g., over a communication network). For example, the controller 3200 can be a controller of a liquid-to-air cooling unit (e.g., LACU 100, 200, 1600, 2500) an application programming interface, command line interface, or web interface can be provided for a liquid-to-air cooling unit to allow an operator to control the liquid-to-air cooling unit remotely.

In some embodiments, the Memory can include any suitable storage device or devices that can be used to store instructions, values, etc., that can be used, for example, by the Processor of the controller 3200 to implement control loops and algorithms, to store logs of the controller 3200, etc. The Memory can include any suitable volatile memory, non-volatile memory, storage, or any suitable combination thereof. For example, the Memory can include random access memory (RAM), read-only memory (ROM), electronically-erasable programmable read-only memory (EEPROM), one or more flash drives, one or more hard disks, one or more solid state drives, one or more optical drives, etc. In some embodiments, the Memory can have encoded thereon a computer program for controlling operation of the Controller 3200.

FIG. 33 illustrates an example process 3300 which can be performed by a control system of a liquid-to-air cooling unit (e.g., control system 3100 shown in FIG. 31). At block 3302, the process can select or switch an operating mode of a cooling unit (e.g., LACU 100, 200, 1600, or 2500). An operating mode can include system parameters for operation of components of a cooling unit (e.g., maximum and minimum speeds of pumps and/or motors, a primary and secondary controller, a set point for a temperature, differential temperature, flow rate, pressure, differential pressure, etc.). As another example, a mode can include a mode of a feedback loop control procedure, as described with respect to FIGS. 27 and 28 (e.g., modes for operation of respective PID controls). Further, in some cases, an operating mode can include a mode of one or more pumps of an RPU (e.g., pumps 2503 of RPU 2501 shown in FIG. 25). For example, pumps can be operated in a parallel mode, with each pump operating to induce a flow through an RPU of a LACU. Alternatively, pumps of an RPU can operate in an active/passive configuration, with one pump being a primary pump and another pump being activated only when the primary pump is not operational. An operating mode can further include which controller of a pair of controllers (e.g., Controller 1 and Controller 2 shown in FIG. 31) to use to implement a control system for the LACU. In some examples, a user input can be provided to select or switch an operating mode. In some cases, system parameters can dictate an operating mode, as, for example, when failure of a feedback sensor of an active PID control system necessitates a switch to a PID control for another feedback sensor, as described with respect to FIGS. 27 and 28.

At block 3304, the system can receive target output values and operating parameters. In some examples, this can include performing a lookup on a database, or otherwise retrieving the values and parameters from a memory that is operatively connected to a processor implementing the process 3300. In some cases, an operator can be prompted for input to set one or more target output values and operating parameters. In some cases, operating values and target parameters can be values for operational parameters listed in FIGS. 30A-1 through 30B-2.

At block 3306, a system implementing the process 3300 can measure an output at a target sensor. The target sensor can be a feedback sensor for a PID control implementation, as illustrated in FIGS. 27 and 28. In some cases the target sensor can be a sensor for which an operating range has been set (e.g., the target can be a sensor for a temperature for which the system include a maximum and/or minimum value for the output of the sensor). In some cases, the output from the target sensor is informational, and can be provided to a user at a display or other interface of a liquid to air cooling unit.

At block 3308, the system implementing the process 3300 can check if the output matches a target. In some cases, the target is a target range for the output value (e.g., as set at block 3304). In some cases, the target is a set point of a PID controller for the output of the target sensor.

If the output matches the target value (e.g., a sensed temperature is within a target range, a temperature at an outlet of a LACU equals a set point for the temperature), the process 3300 can return to block 3302 to monitor for any updates to the system that can require switching an operating mode of the system.

If, at block 3308, the output does not match the target, as when a measured value from a sensor falls outside of a specified range, or does not equal a set value, the system can provide a signal to an actuator. The signal can include instructions to increase or decrease a pump speed, as described in FIG. 27, or to increase or decrease a speed of one or more fans, as described in FIG. 28. In some examples, the signal can include instructions to shut down or halt a respective actuator (e.g., one or more of the fans and pumps 2514, 2503 shown in FIG. 25), as when the output indicates a measured value falling outside of a safe operating range. In other examples, an actuator can include a valve to selectively allow or deny fluid flow through portions of a cooling unit (e.g., LACU 100, 200, 1600, 2500, etc.). In some cases, the signal can be calculated based on an output of a PID control, as described with respect to FIGS. 27 and 28. Upon providing the signal to the actuator, the system implementing the process 3300 can return to block 3302 to continue monitoring conditions of the cooling systems

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A high-density liquid cooling system comprising:
a cabinet including side panels on opposing sides of the cabinet;
a heat exchanger within the cabinet, the heat exchanger being positioned at an oblique angle relative to the side panels, the heat exchanger being fluidly positioned along a liquid cooling circuit and including a fluid inlet for receiving a fluid of the liquid cooling circuit;
a fan assembly mounted at a front of the cabinet, the fan assembly including a plurality of fans, the plurality of fans being configured to generate an air flow across a surface of the heat exchanger;
a pumping unit within the cabinet, the pumping unit including a control unit and a first pump for inducing a flow of the fluid of the liquid cooling circuit, the control unit including a first removable controller and a second removable controller, and the control unit being in electronic communication with the first pump and at least one fan of the plurality of fans.

2. The high-density liquid cooling system of claim 1, further comprising:
a filter assembly within the cabinet, the filter assembly being fluidly positioned along the liquid cooling circuit and including:
a first valve;
a second valve;
a primary filter along a primary flow path, the primary flow path being defined by the first valve and the second valve;
a secondary filter along a secondary flow path, the secondary flow path being defined by the first valve and the second valve;
a differential pressure sensor, wherein the differential pressure sensor is configured to sense a difference between a pressure upstream of the first filter and a pressure downstream of the filter,
wherein, when the first and second valves are in a first position, the fluid of the liquid cooling circuit flows through the primary flow path, and when the first and second valves are in a second position, the fluid of the liquid cooling circuit flows through the secondary flow path.

3. The high-density liquid cooling system of claim 1, wherein the first pump is downstream of the heat exchanger.

4. The high-density liquid cooling system of claim 1, wherein the pumping unit includes a second pump.

5. The high-density liquid cooling system of claim 4, where each of the first and second pumps are arranged on pump cassettes, and include blind mate connectors for connecting with corresponding blind mate connectors of the pumping unit.

6. The high-density liquid cooling system of claim 1, wherein the first removable controller is housed in a first cartridge including an engagement tab, wherein a displacement of the engagement tab disengages a retention feature of the pumping unit to allow removal of the first cartridge from the pumping unit.

7. The high-density liquid cooling system of claim 1, further comprising a power supply unit within the cabinet, the power supply unit comprising a plurality of removable power supply modules.

8. The high-density liquid cooling system of claim 1, including a baffle plate positioned along one of the opposing sides of the cabinet.

9. The high-density liquid cooling system of claim 1, wherein the first controller is a primary controller and the second controller is a backup controller.

10. The high-density liquid cooling system of claim 1, further comprising a supply manifold and a return manifold, each of the supply manifold and the return manifold including at least two ports for fluidly connecting two hoses of the high-density cooling system to the manifold.

11. The high-density liquid cooling system of claim 1, wherein the pumping unit is positioned in a bottom slot of the cabinet.

12. The high-density liquid cooling system of claim 1, wherein each fan of the plurality of fans includes a handle and a blind mate connector.

13. The high-density liquid cooling system of claim 1, wherein the pumping unit has a height of 4 rack units.

14. The high-density liquid cooling system of claim 1, further comprising a first expansion tank upstream of the heat exchanger.

15. An in-row liquid cooling system comprising:
a liquid-to-air heat exchanger positioned along a liquid cooling circuit, the liquid-to-air heat exchanger including a liquid inlet and a liquid outlet;
a pumping unit including a liquid pump, the liquid pump being configured to generate a fluid flow in a liquid coolant of the liquid cooling circuit;
a fan, the fan being configured to generate an air flow across a surface of the liquid-to-air heat exchanger;
a first sensor configured to measure a first value of a first parameter of the liquid coolant;
a second sensor configured measure a second value of a second parameter of the liquid coolant;
a controller in electrical communication with each of the liquid pump, the fan, the first sensor and the second sensor, the controller including a processor configured to:
receive, from the first sensor, the first value;
receive, from the second sensor, the second value;
based on a comparison of the first value with a target value for the first parameter, output to the liquid pump, a signal to change a speed of the liquid pump; and
based on a comparison of the second value with a target value for the second parameter, output to the fan a signal to change a speed of the fan.

16. The in-row liquid cooling system of claim 15, further comprising a third sensor configured to measure a third value for a third parameter of the liquid coolant, wherein the processor is further configured to:
receive, from the third sensor, the third value;
detect a loss of communication with the first sensor; and
when a loss of communication with the first sensor is detected, based on a comparison of the third value with a target value for the third parameter, output to the liquid pump a signal to change a speed of the liquid pump.

17. The in-row liquid cooling system of claim 15, wherein the fan is one of a plurality of fans, each of the plurality of fans being configure to produce an air flow across the surface of the liquid-to-air heat exchanger.

18. A method of manufacturing and operating a cooling system, the method comprising:
providing an enclosure including side panels at opposing lateral sides of the enclosure;
mounting, within the enclosure, an air-to-liquid heat exchanger, the air-to-liquid heat exchanger being mounted at an oblique angle relative to the side panels;
mounting, within the enclosure, a replaceable pump unit, the replaceable pump unit including at least two pumps and a control unit including two removable control modules;
mounting, at a front of the enclosure, a fan assembly, the fan assembly including a plurality of removable fans;
fluidly connecting the air-to-liquid heat exchanger with at least one pump cassette of the at least two pump cassettes;
electronically coupling a first replaceable control module of the two removable control modules to at least one of the fans of the plurality of fans, and at least one pump of the at least two pumps;
regulating, using at the at least one of the fans, and in response to a signal from the first replaceable control module, an air flow across the air-to-liquid heat exchanger;
regulating, using the at least one pump, a flow of fluid through the air-to-liquid heat exchanger, in response to a signal from the first replaceable control module.

19. The method of claim 18, further comprising, mounting, within the enclosure, a power supply unit, the power supply unit including a plurality of removable power supply modules.

20. The method of claim 18, further comprising fluidly connecting an air bleed valve to the air-to-liquid heat exchanger at a fluid port of the air-to-liquid heat exchanger.
